(19) United States
(12) Patent Application Publication
(10) Pub. No.: US 2023/0131636 A1
(43) Pub. Date: Apr. 27, 2023

(54) MICRO LIGHT-EMITTING DIODE PACKAGE STRUCTURE

(71) Applicant: Lextar Electronics Corporation, Hsinchu (TW)

(72) Inventors: Shiou-Yi KUO, Hsinchu (TW); Guo-Yi SHIU, Hsinchu (TW); Chih-Hao LIN, Hsinchu (TW); Min-Che TSAI, Hsinchu (TW); Jian-Chin LIANG, Hsinchu (TW)

(21) Appl. No.: 17/970,487

(22) Filed: Oct. 20, 2022

Related U.S. Application Data
(60) Provisional application No. 63/270,654, filed on Oct. 22, 2021.

(30) Foreign Application Priority Data
Sep. 28, 2022 (TW) 111136672

(51) Int. Cl. H01L 25/16; H01L 33/54; H01L 33/62; H01L 33/60

(52) U.S. Cl. CPC H01L 25/167; H01L 33/54; H01L 33/62; H01L 33/60

(57) ABSTRACT

Embodiments provide a micro light-emitting diode package structure and a method for forming the same. The micro light-emitting diode package structure includes a redistribution layer, a control device, micro light-emitting diodes, and a flexible material layer. The control device and the micro light-emitting diodes are disposed on and electrically connected to the redistribution layer. The flexible material layer covers the control device and the micro light-emitting diodes, wherein the micro light-emitting diodes are in contact with the flexible material layer.

### CROSS REFERENCE TO RELATED APPLICATIONS

This application claims the benefit of U.S. Provisional Application No. 63/270,654, filed on Oct. 22, 2021 and claims priority of Taiwan Patent Application No. 111136672, filed on Sep. 28, 2022, which are incorporated by reference herein in their entireties.

### BACKGROUND OF THE DISCLOSURE

### Field of the Disclosure

The present disclosure relates to a micro light-emitting diode package structure, and, in particular, to a micro light-emitting diode package structure.

### Description of the Related Art

Since light-emitting diodes (LEDs) have the advantage of low power consumption, light-emitting diode displays have become the mainstream in the field of display technology. However, it is hard to reduce the thickness and size of light-emitting diodes any further, and it is difficult for current packaging technology to achieve the goals of having smaller pitch sizes and lower costs.

### BRIEF SUMMARY OF THE DISCLOSURE

An embodiment of the present disclosure provides a micro light-emitting diode package structure. The micro light-emitting diode package structure includes a redistribution layer, a control device, micro light-emitting diodes and a flexible material layer. The control device and the micro light-emitting diode are disposed on the redistribution conductive structure and electrically connected to the redistribution layer. The flexible material layer covers the control device and the micro light-emitting diodes, wherein the micro light-emitting diodes are in contact with the flexible material layer.

### BRIEF DESCRIPTION OF THE DRAWINGS

The present disclosure can be more fully understood by reading the subsequent detailed description and examples with references made to the accompanying drawings, wherein:

FIGS. 1 to 14 are schematic cross-sectional views of a micro light-emitting diode packaging structure in accordance with some embodiments of the disclosure;

FIG. 15 is a bottom view of a micro light-emitting diode package structure in accordance with some embodiments of the disclosure, which shows the relationship between the area (AD) of the distributed Bragg reflector (DBR) layer and the total area (AT) of the micro light-emitting diode package structure;

FIG. 16 is a schematic cross-sectional view of a micro light-emitting diode of the micro light-emitting diode package structure in accordance with some embodiments of the disclosure, which shows the profile of the back surface of the micro light-emitting diode;

FIGS. 17A-17K are schematic cross-sectional views at different stages of forming the micro light-emitting diode package structure shown in FIG. 1 in accordance with some embodiments of the disclosure;

FIGS. 18A-18E are schematic cross-sectional views at different stages of forming the micro light-emitting diode package structure shown in FIG. 1 in accordance with some embodiments of the disclosure;

FIGS. 19A-19J are schematic cross-sectional views at different stages of forming the micro light-emitting diode package structure shown in FIG. 2 in accordance with some embodiments of the disclosure;

FIGS. 20A-201 are schematic cross-sectional views at different stages of forming the micro light-emitting diode package structure shown in FIG. 3 in accordance with some embodiments of the disclosure;

FIGS. 21A-211 are schematic cross-sectional views at different stages of forming the micro light-emitting diode package structure shown in FIG. 4 in accordance with some embodiments of the disclosure;

FIGS. 22A-221 are schematic cross-sectional views at different stages of forming the micro light-emitting diode package structure shown in FIG. 5 in accordance with some embodiments of the disclosure;

FIGS. 23A-23H are schematic cross-sectional views at different stages of forming the micro light-emitting diode package structure shown in FIG. 6 in accordance with some embodiments of the disclosure;

FIGS. 24A-24H are schematic cross-sectional views at different stages of forming the micro light-emitting diode package structure shown in FIG. 7 in accordance with some embodiments of the disclosure;

FIGS. 25A-25D are schematic cross-sectional views at different stages of forming the micro light-emitting diode package structure shown in FIG. 8 in accordance with some embodiments of the disclosure;

FIGS. 26A-26G are schematic cross-sectional views at different stages of forming the micro light-emitting diode package structure shown in FIG. 9 in accordance with some embodiments of the disclosure;

FIGS. 27A-27D are schematic cross-sectional views at different stages of forming the micro light-emitting diode package structure shown in FIG. 10 in accordance with some embodiments of the disclosure;

FIGS. 28A-28F are schematic cross-sectional views at different stages of forming the micro light-emitting diode package structure shown in FIG. 11 in accordance with some embodiments of the disclosure;

FIGS. 29A-29E are schematic cross-sectional views at different stages of forming the micro light-emitting diode package structure shown in FIG. 12 in accordance with some embodiments of the disclosure;

FIGS. 30A-30C are schematic cross-sectional views at different stages of forming the micro light-emitting diode package structure shown in FIG. 13 in accordance with some embodiments of the disclosure; and

FIGS. 31A-31C are schematic cross-sectional views at different stages of forming the micro light-emitting diode package structure shown in FIG. 14 in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

The embodiments of the present disclosure are described fully hereinafter with reference to the accompanying drawings, and the advantages and features of the present disclosure and methods of achieving them will be apparent from the following exemplary embodiments that will be described in more detail with reference to the accompanying drawings. It should be noted, however, that the present disclosure is not limited to the following exemplary embodiments, and may be implemented in various forms. Accordingly, the exemplary embodiments are provided only to disclose the present disclosure and let those skilled in the art know the category of the present disclosure. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

Embodiments of the disclosure provide a micro light-emitting diode package structure and a method for forming the same. The micro light-emitting diode package structure integrates a control device and micro light-emitting diodes in the same package structure to form a pixel package, which can be individually/independently controlled. In addition, the volume of the package structure can be further reduce for application in small-pitch displays, such as wearable display devices or special totem micro-light sources.

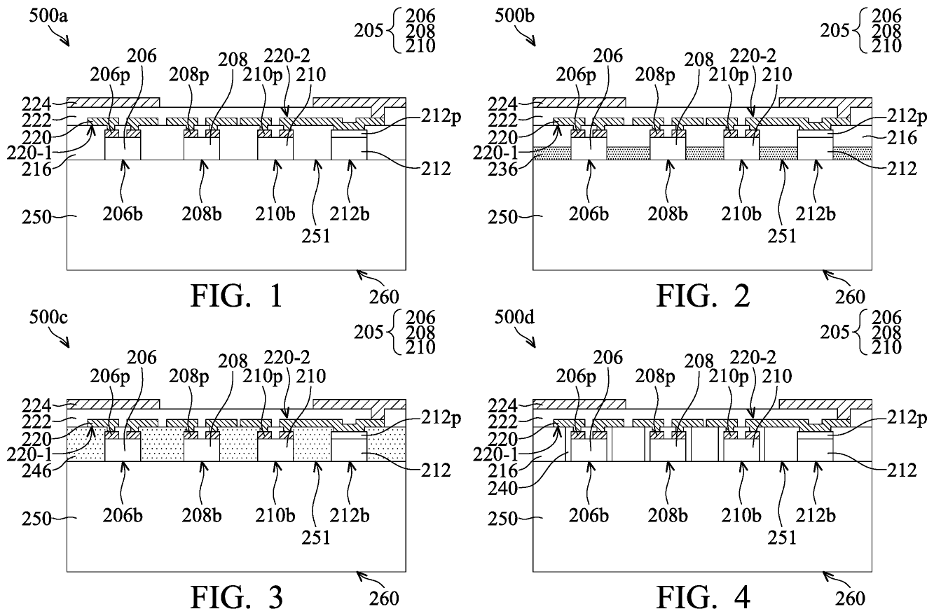

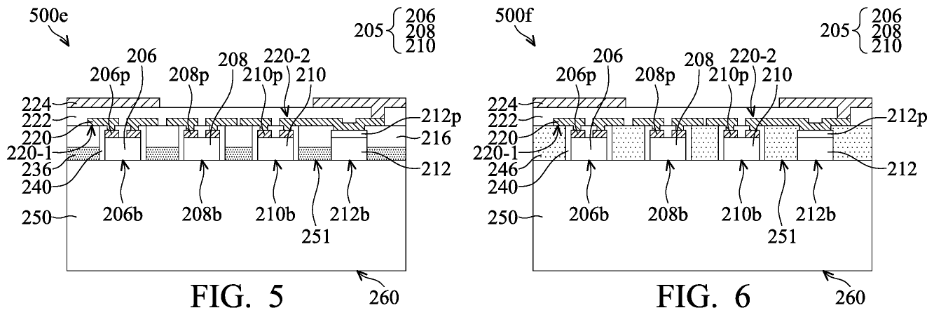

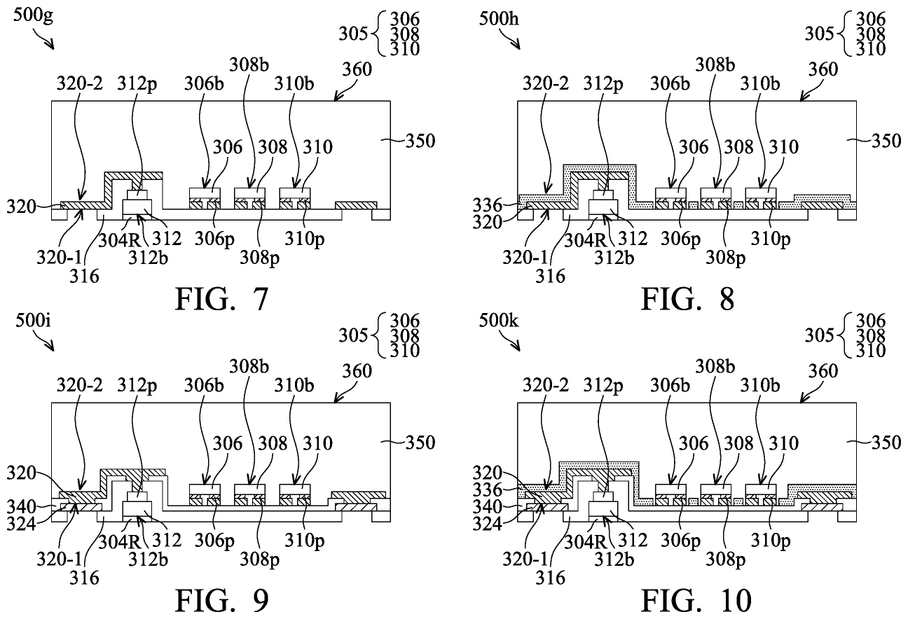

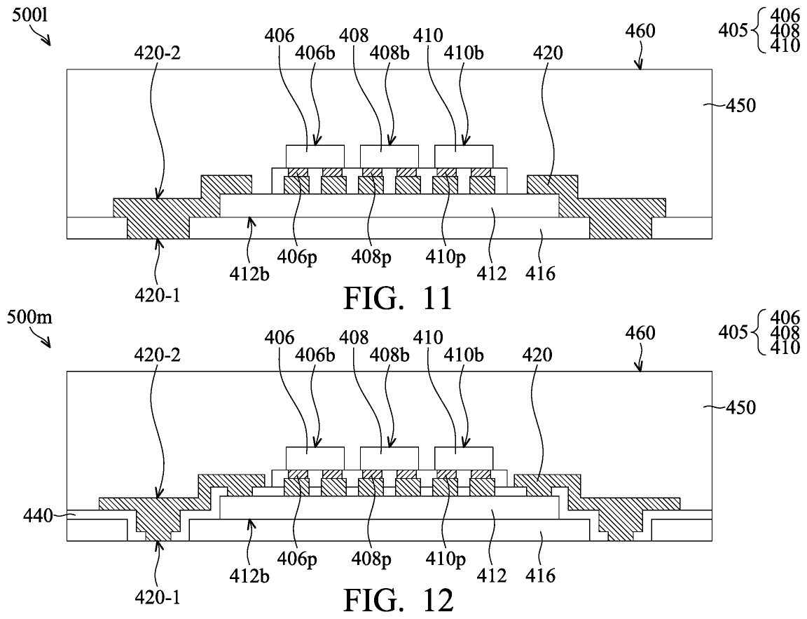

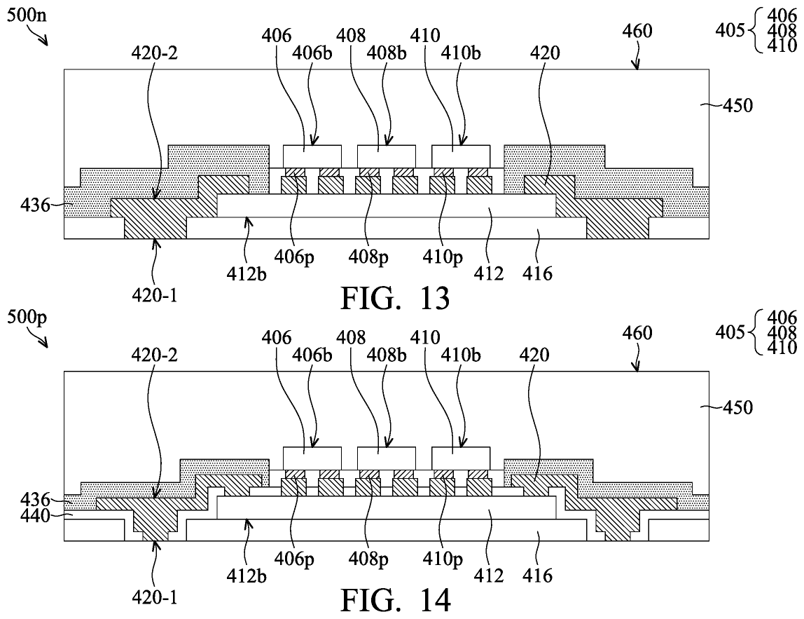

A micro light-emitting diode (LED) package structure 500 including the micro LED package structures 500a-500i, 500k-500n and 500p in accordance with some embodiments of the disclosure will be described below with reference to FIGS. 1-14. FIG. 1 is a schematic cross-sectional view of a micro light-emitting diode package structure 500a in accordance with some embodiments of the disclosure. The micro light-emitting diode package structure 500a includes a redistribution layer (RDL) 220, a control device 212, micro light-emitting diodes 205 (including micro light-emitting diodes 206, 208 and 210), and a flexible material layer 250. As shown in FIG. 1, the redistribution layer 220 has a first side 220-1 and a second side 220-2 that are opposite to each other. The redistribution layer 220 is disposed over the micro light-emitting diodes 206, 208 and 210 and the control device 212. In addition, the redistribution layer 220 is electrically connected to the micro light-emitting diodes 206, 208 and 210 and the control device 212. The redistribution layer 220 is used as fan-out routings to reroute the original positions of the electrical nodes of the micro light-emitting diodes 205 and the control device 212 to the designated positions of the micro light-emitting diode package structure. In some embodiments, the redistribution layer 220 includes a stack of conductive materials layers formed of, for example, chromium (Cr), aluminum (Al), nickel (Ni), gold (Au), platinum (Pt), tin (Sn), copper (Cu), or a combination thereof In addition, the redistribution layer 220 may be formed by a plating process such as evaporation or electroplating.

As shown in FIG. 1, the control device 212 and the micro light-emitting diodes 205, which are separated from each other, are disposed side by side on the first side 220-1 of the redistribution layer 220 and electrically connected to the redistribution layer 220. The control device 212 has a contact pad 212p and a back surface 212b that are located away from the contact pad 212p. In addition, the micro light-emitting diodes 206, 208 and 210 respectively have electrodes 206p, 208p and 210p and back surfaces 206b, 208b and 210b that are located away from the electrodes 206p, 208p and 210p. In some embodiments, the back surfaces 206b, 208b, and 210b of the micro light-emitting diodes 206, 208, and 210 are also light-emitting surfaces of the micro light-emitting diodes 206, 208, and 210. The redistribution layer 220 is disposed on the electrodes 206p, 208p and 210p of the micro light-emitting diodes 206, 208 and 210 and the contact pad 212p of the control device 212. In addition, the redistribution layer 220 is in contact with the electrodes 206p, 208p and 210p of the micro light-emitting diodes 206, 208 and 210 and contact pad 212p of control device 212. In some embodiments, the back surface 212b of the control device 212 is leveled with the back surfaces 206b, 208b and 210b of the micro light-emitting diodes 206, 208 and 210. In some embodiments, the control device 212 includes a micro integrated circuit (IC) driver device, a micro control IC device, or a combination thereof In some embodiments, the micro light-emitting diodes 205 include the micro light-emitting diodes 206, 208 and 210 that emit lights of different wavelengths to form a pixel unit. For example, the micro light-emitting diodes 205 emitting lights of different colors may include the micro light-emitting diode 206 emitting red light, the micro light-emitting diode 208 emitting green light, and the micro light-emitting diode 210 emitting blue light. However, embodiments of the disclosure are not limited thereto. In some embodiments, the micro light-emitting diodes 205 include the micro light-emitting diodes 206, 208 and 210 that emit light of the same wavelength, such as blue light or ultraviolet (UV) light, and are respectively coated with phosphors or quantum dot materials in different compositions to absorb the light emitted from the micro light-emitting diodes 206, 208 and 210 and convert them into red light, green light or blue light, to form a pixel unit.

As shown in FIG. 1, the flexible material layer 250 covers and contacts the back surface 212b of the control device 212 and the back surfaces 206b, 208b and 210b of the micro light-emitting diodes 206, 208 and 210. An interface 251 between the control device and the flexible material layer 250 is located away from the electrodes of the micro light-emitting diodes 206, 208 and 210. A light-emitting surface 260 of the micro light-emitting diode package structure 500a is on the surface of the flexible material layer 250 opposite the interface 251. In some embodiments, the flexible material layer 250 includes a flexible material with good light transmittance (for example, the light transmittance is greater than 90%), such as polymethyl methacrylate (PMMA), polyethylene terephthalate (PET), polyethylene naphthalate (PEN), polystyrene (PS), polypropylene (PP), polyamide (PA), polycarbonate (PC), polyimide (PI), epoxy, silicone, polydimethylsiloxane (PDMS) or a combination of any two or more of the above materials, and can be formed by, for example, film pasting or spray coating.

As shown in FIG. 1, the micro light-emitting diode package structure 500a further includes an insulating layer 216 disposed between the first side 220-1 of the redistribution layer 220 and the flexible material layer 250. The insulating layer 216 is in contact with the redistribution layer 220 and the flexible material layer 250. In addition, the insulating layer 216 surrounds the control device 212 and the micro light-emitting diodes 206, 208 and 210 and covers the electrodes 206p, 208p, 210p and the contact pad 212p to provide the electrical insulation between the control device 212 and the micro light-emitting diodes 206, 208 and 210. As shown in FIG. 1, the redistribution layer 220 passes through a portion of the insulating layer 216 located above the control device 212 and the micro light-emitting diodes 206, 208 and 210 to be electrically connected to the electrodes 206p, 208p and 210p of the micro light-emitting diodes 206, 208 and 210 and the contact pads 212p of control device 212. As shown in FIG. 1, the back surface 212b of the control device 212 and the back surfaces 206b, 208b and 210b of the micro light-emitting diodes 206, 208 and 210 are exposed from the insulating layer 216. In some embodiments, the height of the insulating layer 216 between the redistribution layer 220 and the flexible material layer 250 is greater than the heights of the micro light-emitting diodes 206, 208, 210 and the control device 212, in order to provide better electrical isolation. In some embodiments, the insulating layer 216 includes polyimide (PI), epoxy, benzocyclobutene (BCB) and other insulating materials with low dielectric constant and good step coverage, and can be formed by a coating process, for example, spin coating or spray coating.

As shown in FIG. 1, the micro light-emitting diode package structure 500a further includes an insulating layer 222 and bonding pads 224 as an interconnect structure. As shown in FIG. 1, the insulating layer 222 is disposed on the second side 220-2 of the redistribution layer 220 and covers the redistribution layer 220 to serve as an electrical insulating feature between the redistribution layers 220. As shown in FIG. 1, the bonding pads 224 are disposed on the insulating layer 222, pass through the insulating layer 222 and are electrically connected to the redistribution layers 220, and are used to electrically connect to external circuits. In some embodiments, the insulating layer 216 and the insulating layer 222 may have the same or similar materials and processes. In some embodiments, the bonding pads 224 and the redistribution layer 220 may have the same or similar materials and formation processes.

FIG. 2 is a schematic cross-sectional view of a micro light-emitting diode package structure 500b in accordance with some embodiments of the disclosure, and the reference numbers the same or similar as those previously described with reference to FIG. 1 denote the same or similar elements. As shown in FIG. 2, the difference between the micro light-emitting diode package structure 500b and the micro light-emitting diode package structure 500a is that the micro light-emitting diode package structure 500b includes a light shielding layer 236 disposed between the redistribution layer 220 and the flexible material layers 250 to improve the contrast of the micro light-emitting diode package structure 500b. As shown in FIG. 2, the light shielding layer 236 is in contact with the insulating layer 216 and the flexible material layer 250, surrounds the micro light-emitting diodes 206, 208 and 210, and is close to the back surfaces 206b, 208b and 210b of the micro light-emitting diodes 206, 208 and 210. When the micro light-emitting diodes 206, 208 and 210 emit light from the back surfaces 206b, 208b and 210b, the light shielding layer 236 may include a black matrix. In some embodiments, the light shielding layer 236 includes a colloidal material and an inorganic material, and the colloidal material includes polymethyl methacrylate (PMMA), polycarbonate (PC), diethylene glycol bis(allyl carbonate) (CR-39), polystyrene (PS), epoxy, polyamide, acrylate, silicone or a combination of thereof The inorganic material may include carbon powder or perovskite. In some embodiments, the light shielding layer 236 includes another colloidal material and another organic material, and the organic material includes polyimide, poly-vinyl alcohol resin and/or acrylic added with black pigment or dye. In some embodiments, the light shielding layer 236 is formed by, for example, spin coating or molding.

FIG. 3 is a schematic cross-sectional view of a micro light-emitting diode package structure 500c in accordance with some embodiments of the disclosure, and the reference numbers the same or similar as those previously described with reference to FIGS. 1 and 2 denote the same or similar elements. As shown in FIG. 3, the difference between the micro light-emitting diode package structure 500c and the micro light-emitting diode package structure 500a is that the micro light-emitting diode package structure 500c includes a light shielding layer 246 between the redistribution layer 220 and the flexible material layer 250. As shown in FIG. 3, the light-shielding layer 246 can replace the insulating layer 216 of the micro light-emitting diode package structure 500a, which simultaneously provides electrical insulation and improves the contrast of the micro light-emitting diode package structure 500c. In some embodiments, the light shielding layer 236 and the light shielding layer 246 may have the same or similar materials and formation processes.

FIG. 4 is a schematic cross-sectional view of a micro light-emitting diode package structure 500d in accordance with some embodiments of the disclosure, and the reference numbers the same or similar as those previously described with reference to FIGS. 1-3 denote the same or similar elements. As shown in FIG. 4, the difference between the micro light-emitting diode package structure 500d and the micro light-emitting diode package structure 500a is that the micro light-emitting diode package structure 500d includes a distributed Bragg reflector (DBR) layer 240 close to the electrodes 206p, 208p and 210p of the micro light-emitting diodes 206, 208 and 210 and in contact with the redistribution layer 220 to increase the luminous efficiency of the micro light-emitting diode package structure 500d. In some embodiments, the distributed Bragg reflector layer 240 surrounds the micro light-emitting diodes 206, 208 and 210 and extends along sidewalls of the micro light-emitting diodes 206, 208 and 210 to be close to the electrodes 206p, 208p and 210p. The distributed Bragg reflector layer 240 is in contact with the redistribution layer 220 and the insulating layer 216. In addition, the electrodes 206p, 208p and 210p of the micro light-emitting diodes 206, 208 and 210 are exposed from the distributed Bragg reflector layer 240. The distributed Bragg reflector layer 240 separates the sidewalls of the micro light-emitting diodes 206, 208 and 210 from the insulating layer 216. In some embodiments, the distributed Bragg reflector layer 240 is composed of a stack of alternating two or more thin films of homogeneous or heterogeneous materials with different refractive indices. For example, the distributed Bragg reflector layer 240 may be composed of a stack of alternating silicon dioxide (SiO₂) layers and titanium dioxide (TiO₂) layers, a stack of alternating silicon dioxide (SiO₂) layers, aluminum oxide (Al₂O₃) layers and titanium dioxide (TiO₂) layers, or a stack of alternating titanium dioxide (TiO₂) layers, silicon dioxide (SiO₂) layers and tantalum pentoxide (Ta₂O₅) layers. In some embodiments, the distributed Bragg reflector layer 240 is formed by a deposition process such as evaporation, atomic layer deposition (ALD), metal organic vapor chemical deposition (MOCVD), and a subsequent patterning process.

FIG. 5 is a schematic cross-sectional view of a micro light-emitting diode package structure 500e in accordance with some embodiments of the disclosure, and the reference numbers the same or similar as those previously described with reference to FIGS. 1-4 denote the same or similar elements. As shown in FIG. 5, the difference between the micro light-emitting diode package structure 500e and the micro light-emitting diode package structure 500a is that the micro light-emitting diode package structure 500e includes the light shielding layer 236 and the distributed Bragg reflector layer 240 disposed between the redistribution layer 220 and the flexible material layers 250 to simultaneously improve the contrast and luminous efficiency of the micro light-emitting diode package structure 500e. As shown in FIG. 5, the light shielding layer 236 surrounds the micro light-emitting diodes 206, 208, 210 and contacts the distributed Bragg reflector layer 240 extending along the sidewalls of the micro light-emitting diodes 206, 208 and 210. The distributed Bragg reflector layer 240 separates the micro light-emitting diodes 206, 208 and 210 from the insulating layer 216 and the light shielding layer 236.

FIG. 6 is a schematic cross-sectional view of a micro light-emitting diode package structure 500f in accordance with some embodiments of the disclosure, and the reference numbers the same or similar as those previously described with reference to FIGS. 1-5 denote the same or similar elements. As shown in FIG. 6, the difference between the micro light-emitting diode package structure 500f and the micro light-emitting diode package structure 500c is that the micro light-emitting diode package structure 500f includes the distributed Bragg reflector layer 240 surrounding the micro light-emitting diodes 206, 208 and 210 to further increase the luminous efficiency of the micro light-emitting diode package structure 500f. In some embodiments, the distributed Bragg reflector layer 240 separates the micro light-emitting diodes 206, 208 and 210 from the light shielding layer 246.

FIG. 7 is a schematic cross-sectional view of a micro light-emitting diode package structure 500g in accordance with some embodiments of the disclosure, and the reference numbers the same or similar as those previously described with reference to FIGS. 1-6 denote the same or similar elements. As shown in FIG. 7, the micro light-emitting diode package structure 500g includes a redistribution layer 320, a control device 312, micro light-emitting diodes 305 (including micro light-emitting diodes 306, 308 and 310) and a flexible material layer 350. In some embodiments, the control device 312 may have the same or similar structure as the control device 212. The micro light-emitting diodes 305 (including the micro light-emitting diodes 306, 308 and 310) may have the same or similar structure as the micro light-emitting diodes 205 (including the micro light-emitting diodes 206, 208 and 210). The redistribution layer 320 may have the same or similar materials and formation methods as the redistribution layer 220. The flexible material layer 350 may have the same or similar materials and formation methods as the flexible material layer 250.

As shown in FIG. 7, the difference between the micro light-emitting diode package structure 500a and the micro light-emitting diode package structure 500g is that the redistribution layer 320 of the micro light-emitting diode package structure 500g has a first side 320-1 and a second side 320-2 that are opposite to each other. The control device 312 is disposed on the first side 320-1 of the redistribution layer 320, and the micro light-emitting diodes 306, 308 and 310 are disposed on the second side 320-2 of the redistribution layer 320. In detail, a contact pad 312p of the control device 312 is in contact with the first side 320-1 of the redistribution layer 320, and electrodes 306p, 308p and 310p of the micro light-emitting diodes 306, 308 and 310 are in contact with the second side 320-2 of the redistribution layer 320. The micro light-emitting diodes 306, 308 and 310 of the micro light-emitting diode package structure 500g are closer to a light-emitting surface 360 of the micro light-emitting diode package structure 500g than the control device 312.

As shown in FIG. 7, an insulating layer 316 is disposed on the first side 320-1 of the redistribution layer 320 and in contact with the control device 312. The insulating layer 316 is located between the redistribution layer 320 and the control device 312. In addition, the redistribution layer 320 passes through a portion of the insulating layer 316 above the control device 312 to be electrically connected to the contact pad 312p of the control device 312. The back surface 312b of the control device 312 exposed from the insulating layer 316 is located away from the contact pad 312p. In addition, the insulating layer 316 has openings to expose the redistribution layer 320 for electrically connecting the redistribution layer 320 to external circuits. In some embodiments, the insulating layer 216 and the insulating layer 316 have the same or similar materials and formation methods.

As shown in FIG. 7, the flexible material layer 350 of the micro light-emitting diode package structure 500g is disposed on the second side 320-2 of the redistribution layer 320. The flexible material layer 350 covers and contacts the redistribution layer 320, sidewalls, the electrodes 306p, 308p, 310p, and the back surfaces 306b, 308b and 310b of the micro light-emitting diodes 306, 308 and 310, and the insulating layer 316 not covered by the redistribution layer 320.

As shown in FIG. 7, the micro light-emitting diode package structure 500g further includes an adhesive layer 304R covering a back surface 312b of the control device 312. In some embodiments, the adhesive layer 304R includes adhesive materials such as benzocyclobutene (BCB), polyimide (PI), epoxy, or silicone.

FIG. 8 is a schematic cross-sectional view of a micro light-emitting diode package structure 500h in accordance with some embodiments of the disclosure, and the reference numbers the same or similar as those previously described with reference to FIGS. 1-7 denote the same or similar elements. As shown in FIG. 8, the difference between the micro light-emitting diode package structure 500h and the micro light-emitting diode package structure 500g is that the micro light-emitting diode package structure 500h includes a light shielding layer 336 between the redistribution layer 320 and the flexible material layers 350 to improve the contrast of the micro light-emitting diode package structure 500h. As shown in FIG. 8, the light shielding layer 336 is disposed on the second side 320-2 of the redistribution layer 320 and conformally covers the redistribution layer 320. The light shielding layer 336 is in contact with the insulating layer 316, the redistribution layer 320 and the flexible material layer 350. The light shielding layer 336 covers the control device 312 and surrounds the micro light-emitting diodes 306, 308 and 310. In addition, the light shielding layer 336 is close to the electrodes 306p, 308p and 310p of the micro light-emitting diodes 306, 308 and 310. In some embodiments, the light shielding layer 236 and the light shielding layer 336 may have the same or similar materials. The light shielding layer 336 may be formed by a coating process, such as spin coating or spray coating.

FIG. 9 is a schematic cross-sectional view of a micro light-emitting diode package structure 500i in accordance with some embodiments of the disclosure, and the reference numbers the same or similar as those previously described with reference to FIGS. 1-8 denote the same or similar elements. As shown in FIG. 9, the difference between the micro light-emitting diode package structure 500g and the micro light-emitting diode package structure 500i is that the micro light-emitting diode package structure 500i includes a distributed Bragg reflector layer 340 close to the electrodes 306p, 308p and 310p of the micro light-emitting diodes 306, 308an 310 and in contact with the redistribution layer 320 to increase the luminous efficiency of the micro light-emitting diode package structure 500i. The distributed Bragg reflector layer 340 is located between the flexible material layer 350 and the insulating layer 316, conformally covers the insulating layer 316, and contacts the first side 320-1 of the redistribution layer 320. In addition, the distributed Bragg reflector layer 340 partially covers the control device 312. In some embodiments, the distributed Bragg reflector layer 240 and the distributed Bragg reflector layer 340 may have the same or similar materials and formation methods.

As shown in FIG. 9, the micro light-emitting diode package structure 500i further includes bonding pads 324. The bonding pads 324 are disposed between the insulating layer 316 and the distributed Bragg reflector layer 340, and electrically connected to the redistribution layer 320. The bonding pads 324 may be exposed from openings in the insulating layer 316 to be electrically connected to the external circuits. In some embodiments, the bonding pads 224 and bonding 324 may have the same or similar materials and formation methods.

FIG. 10 is a schematic cross-sectional view of a micro light-emitting diode package structure 500k in accordance with some embodiments of the disclosure, and the reference numbers the same or similar as those previously described with reference to FIGS. 1-9 denote the same or similar elements. As shown in FIG. 10, the difference between the micro light-emitting diode package structure 500k and the micro light-emitting diode package structure 500g is that the micro light-emitting diode package structure 500k includes the distributed Bragg reflector layer 340 that is disposed on the first side 320-1 of the redistribution layer 320 and the light shielding layer 336 that is disposed on the second side 320-2 of the redistribution layer 320 to improve the contrast and luminous efficiency of the micro light-emitting diode package structure 500e. As shown in FIG. 10, the distributed Bragg reflector layer 340 close to an edge of the micro light-emitting diode package structure 500k and the light shielding layer 336 close to the electrodes 306p, 308p and 310p of the micro light-emitting diodes 306, 308 and 310 are in contact with each other.

FIG. 11 is a schematic cross-sectional view of a micro light-emitting diode package structure 5001 in accordance with some embodiments of the disclosure, and the reference numbers the same or similar as those previously described with reference to FIGS. 1-10 denote the same or similar elements. As shown in FIG. 11, the micro light-emitting diode package structure 5001 includes a redistribution layer 420, a control device 412, micro light-emitting diodes 405 (including micro light-emitting diodes 406, 408 and 410) and a flexible material layer 450. In some embodiments, the micro light-emitting diodes 405 (including the micro light-emitting diodes 406, 408 and 410) may have the same or similar structure as the micro light-emitting diodes 205 (including the micro light-emitting diodes 206, 208 and 210) and the micro light-emitting diodes 305 (including the micro light-emitting diodes 306, 308 and 310). The redistribution layer 420 may have the same or similar structure and formation methods as the redistribution layers 220 and 320. The flexible material layer 450 may have the same or similar materials and formation methods as the flexible material layers 250 and 350.

As shown in FIG. 11, the difference between the micro light-emitting diode package structure 500a and the micro light-emitting diode package structure 5001 is that the redistribution layer 420 of the micro light-emitting diode package structure 5001 has a first side 420-1 and a second side 420-2 that are opposite to each other. The control device 412 is disposed on the first side 420-1 of the redistribution layer 420, and the micro light-emitting diodes 406, 408 and 410 are disposed on the second side 420-2 of the redistribution layer 420. In detail, the control device 412 is in contact with and electrically connected to the first side 420-1 of the redistribution layer 420. The electrodes 406p, 408p and 410p of the micro light-emitting diodes 406, 408 and 410 are in contact with the second side 420-2 of the redistribution layer 420. In addition, the micro light-emitting diodes 406, 408 and 410 of the micro light-emitting diode package structure 5001 are located directly above the control device 412 and partially overlap with the control device 412. As shown in FIG. 11, the micro light-emitting diodes 406, 408 and 410 are closer to a light-emitting surface 460 of the micro light-emitting diode package structure 5001 than the control device 412. In some embodiments, the control device 412 comprises a thin film transistor device. In other embodiments, the control device 412 includes a micro driver IC device, a micro control IC device, or a combination thereof

As shown in FIG. 11, the insulating layer 416 is disposed on the first side 420-1 of the redistribution layer 420 and contacts the control device 412. The insulating layer 416 covers a back surface 412b of the control device 412 so that the control device 412 is between the insulating layer 416 and the redistribution layer 420. In addition, the control device 412 is located between the insulating layer 416 and the micro light-emitting diodes 406, 408 and 410. In addition, the insulating layer 416 has openings to expose the redistribution layer 420 for electrically connecting the redistribution layer 420 to an external circuit. In some embodiments, the insulating layer 416 serves as a support layer for supporting the control device 412 such as a thin film transistor device.

As shown in FIG. 11, the flexible material layer 450 of the micro light-emitting diode package structure 5001 is disposed on the second side 420-2 of the redistribution layer 420. The flexible material layer 450 covers and contacts the redistribution layer 420, sidewalls and back surfaces 406b, 408b and 410b of the micro light-emitting diodes 406, 408 and 410, and the control device 412 not covered by the redistribution layer 420. The flexible material layer 450 is separated from the insulating layer 416 by the control device 412 and the redistribution layer 420.

FIG. 12 is a schematic cross-sectional view of a micro light-emitting diode package structure 500m in accordance with some embodiments of the disclosure, and the reference numbers the same or similar as those previously described with reference to FIGS. 1-11 denote the same or similar elements. As shown in FIG. 12, the difference between the micro light-emitting diode packaging structure 500m and the micro light-emitting diode packaging structure 5001 is that the micro light-emitting diode packaging structure 500m further includes a distributed Bragg reflector layer 440 close to the electrodes 406p, 408p and 410p of the micro light-emitting diodes 406, 408 and 410 and in contact with the redistribution layer 420 to increase the luminous efficiency of the micro light-emitting diode package structure 500m. The distributed Bragg reflector layer 440 is located between the flexible material layer 450 and the insulating layer 416, conformally covers the control device 412 and the insulating layer 416, and in contact with the first side 420-1 of the redistribution layer 420. In addition, the distributed Bragg reflector layer 440 partially covers the control device 412.

FIG. 13 is a schematic cross-sectional view of a micro light-emitting diode package structure 500n in accordance with some embodiments of the disclosure, and the reference numbers the same or similar as those previously described with reference to FIGS. 1-12 denote the same or similar elements. As shown in FIG. 13, the difference between the micro light-emitting diode package structure 500n and the micro light-emitting diode package structure 5001 is that the micro light-emitting diode package structure 500n further includes a light shielding layer 436 between the redistribution layer 420 and the flexible material layer 450 to improve the contrast of the micro light-emitting diode package structure 500n. As shown in FIG. 13, the light shielding layer 436 is disposed on the second side 420-2 of the redistribution layer 420, and conformally covers the redistribution layer 420. The light shielding layer 436 is in contact with the insulating layer 416, the redistribution layer 420 and the flexible material layer 450. The light shielding layer 436 surrounds the micro light-emitting diodes 406, 408 and 410 and covers the control device 412. In addition, the light shielding layer 436 is close to the electrodes 406p, 408p and 410p of the micro light-emitting diodes 406, 408 and 410.

FIG. 14 is a schematic cross-sectional view of a micro light-emitting diode package structure 500p in accordance with some embodiments of the disclosure, and the reference numbers the same or similar as those previously described with reference to FIGS. 1-13 denote the same or similar elements. As shown in FIG. 14, the difference between the micro light-emitting diode package structure 500p and the micro light-emitting diode package structure 5001 is that the micro light-emitting diode package structure 500p further includes the distributed Bragg reflector layer 440 disposed on the first side 420-1 of the redistribution layer 420 and the light shielding layer 436 disposed on the second side 420-1 of the redistribution layer 420 to simultaneously improve the contrast and luminous efficiency of the micro light-emitting diode package structure 500p. As shown in FIG. 14, the distributed Bragg reflector layer 440 and the light shielding layer 436 close to an edge of the micro LED package structure 500p and the electrodes 406p, 408p and 410p of the micro light-emitting diodes 406, 408 and 410 are in contact with each other.

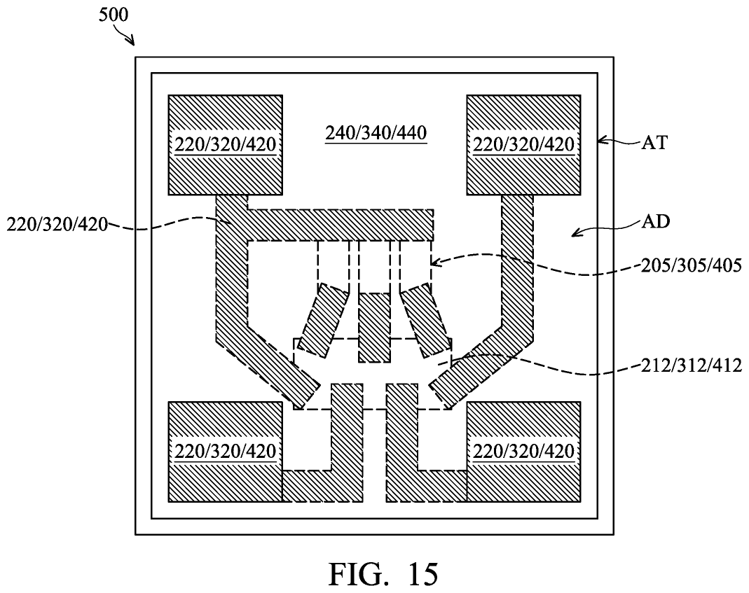

FIG. 15 is a bottom view of the micro light-emitting diode package structure 500 in accordance with some embodiments of the disclosure, which shows the relationship between the area (AD) of the distributed Bragg reflector (DBR) layer and the total area (AT) of a top surface of the micro light-emitting diode package structure. FIG. 15 also shows configuration relationship between the redistribution layers (including the redistribution layers 220, 320 and 420), the micro light-emitting diodes (including the micro light-emitting diodes 205, 305 and 405), the control device (including the control devices 212, 312 and 412) and the distributed Bragg reflector layer (including the distributed Bragg reflector layers 240, 340 and 440). Portions of the redistribution layer at the four corners of the micro light-emitting diode package structure 500 serves as the electrical connections between the anode of each micro light-emitting diode, the common cathode of the micro light-emitting diodes and the external circuit, which can serve as the bonding pads of the micro light-emitting diode package structure 500. In addition, the portions of the redistribution layer with a narrow width between the bonding pad located at the upper left corner of the micro light-emitting diode package structure 500 and each of the micro light-emitting diodes and the control device can serve as one of the conductive lines of the micro light-emitting diode package structure 500 that connects the contact pads of the control device and the cathodes of the respective micro light-emitting diodes to the bonding pad in the upper left corner of the micro light-emitting diode package structure 500. In addition, the portions of the redistribution layer with a narrow width between the three bonding pads located at the upper right corner, the lower right corner and the lower left corner of the micro light-emitting diode package structure 500 and the control device respectively can serve as other conductive lines of the micro light-emitting diode package structure 500. The conductive lines can connect the contact pads of the control device and the anodes of the respective micro light-emitting diodes to the three bonding pads located at the upper right corner, the lower right corner and the lower left corner of the micro light-emitting diode package structure 500, respectively. As shown in FIG. 15, in a plan view of the bottom surface opposite the light-emitting surface (e.g., the light-emitting surfaces 260, 360 and 460) of the micro light-emitting diode package structure 500, the area AD of the distributed Bragg reflector layers 240, 340 and 440 is between 10% and 95% of the total area AT of the top surface of the micro light-emitting diode package structure 500. If the area AD of the distributed Bragg reflector layer is less than 10% of the total area of the top surface AT of the micro light-emitting diode package structure 500, the distributed Bragg reflector layer cannot reflect the light emitted from the micro light-emitting diodes and scattered by the bottom surface to the light-emitting surface, resulting in a poor reflection effect of the micro light-emitting diode package structure 500. If the area AD of the distributed Bragg reflector layer is greater than 95% of the total area AT of the micro light-emitting diode package structure 500, it is difficult to keep the space at the edge of the micro LED package structure 500 for the scribe lines and the electrical connections between the redistribution layer and the external circuit.

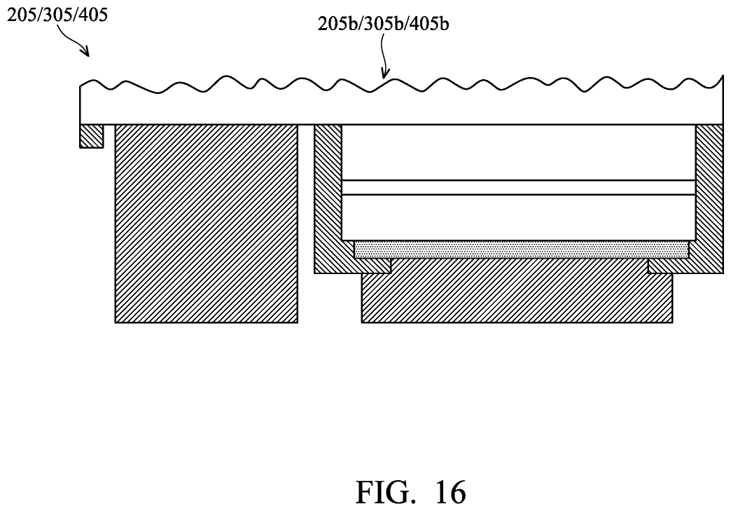

FIG. 16 is an enlarged cross-sectional view of a micro light-emitting diode (including the micro light-emitting diodes 205, 305 and 405) of the micro light-emitting diode package structure 500 in accordance with some embodiments of the disclosure, which shows the profile of the back surfaces 205b, 305b and 405b of the micro light-emitting diodes 205, 305 and 405 and an example structure of the micro light-emitting diodes 205, 305 and 405. As shown in FIG. 16, in the manufacturing processes of the micro light-emitting diodes, a laser lift-off (LLO) method can be used to separate the growth substrate (such as a sapphire substrate) and the semiconductor epitaxial stack structure (including the p-type semiconductor layer, the n-type semiconductor layer and the light-emitting layer) grown thereon to form a micrometer (μm)-scaled micro light-emitting diode. Therefore, one of the back surfaces 205b, 305b and 405b (which can also serve as the light-emitting surfaces) of the micro light-emitting diode 205, 305 and 405 in the micro light-emitting diode package structure 500 is a rough surface, which can reduce the loss caused by the total internal reflection occurring at the interface between the flexible material layer (as shown in FIGS. 1-14) and the back surfaces 205b, 305b and 405b of the micro light-emitting diodes 205, 305 and 405, thereby improving the light extraction efficiency of the micro light-emitting diodes.

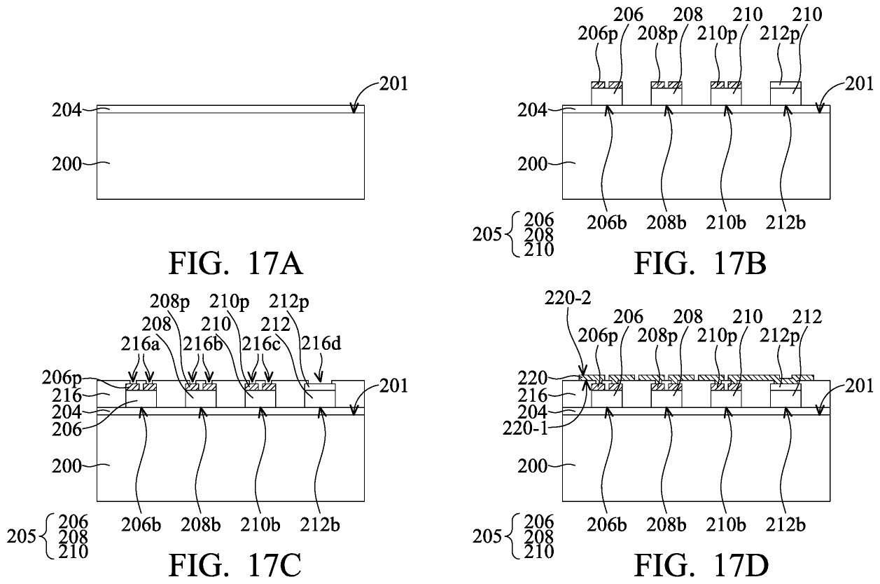

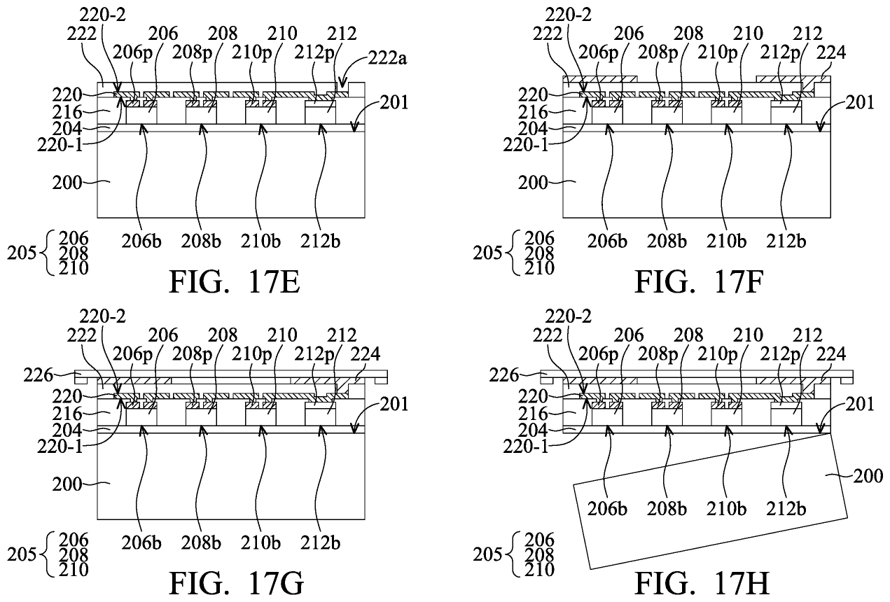

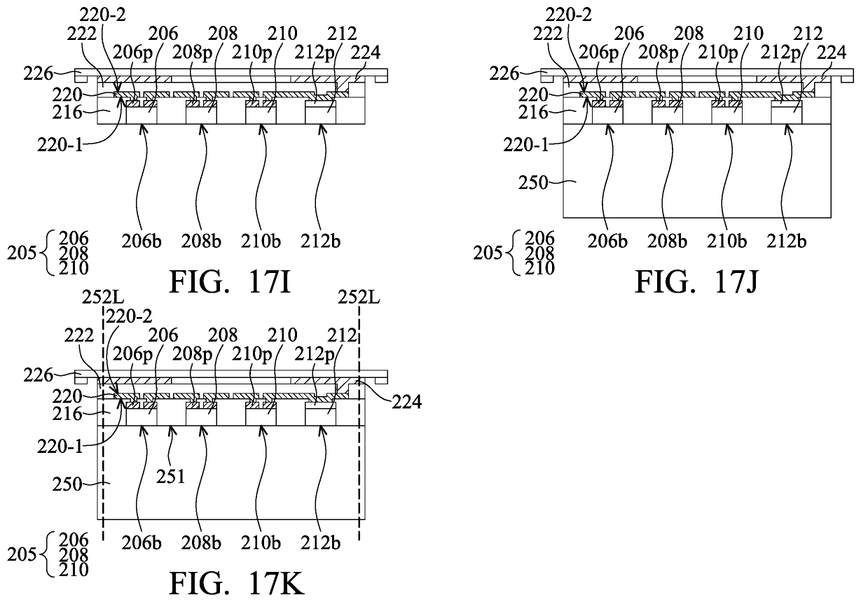

The method for forming the micro light-emitting diode package structure 500 will be described below. FIGS. 17A-17K to FIGS. 31A-31C illustrate methods for forming a micro light-emitting diode package structure (single pixel unit) for the sake of the convenience, though the embodiments of the present disclosure are not limited thereto. In some other embodiments, the methods of forming the light-emitting diode package structure 500 may form periodically arranged micro light-emitting diode package structures.

FIGS. 17A-17K are schematic cross-sectional views at different stages of forming the micro light-emitting diode package structure 500a shown in FIG. 1 in accordance with some embodiments of the disclosure. As shown in FIG. 17A, first, a carrier 200 is provided. The carrier 200 is used to carry the micro light-emitting diodes and control devices to be subsequently transferred onto a surface 201 of the carrier 200. In some embodiments, the material of the carrier 200 includes glass, sapphire, transparent polymer, or a combination thereof. Next, an adhesive layer 204 is coated on the surface 201 of the carrier 200. The adhesive layer 204 is used for adhering the micro light-emitting diodes and the control devices to be subsequently transferred on the carrier 200 on the surface 201 of the carrier 200. In some embodiments, the adhesive layer 204 includes polymer materials having adhesive force and easily to be dissociated and destroyed at the interface with the carrier 200 in the subsequent removal process (such as, laser lift-off (LLO)), for example, polyimide (PI), epoxy, or silicone.

Next, as shown in FIG. 17B, the control device 212 is disposed on the surface 201 of the carrier 200, and micro light-emitting diodes 205 (including the micro light-emitting diodes 206, 208 and 210) are transferred onto the surface 201 of the carrier 200. In addition, the control device 212 and the micro light-emitting diodes 205 are disposed side by side. Further, the back surface 212b of the control device 212 and the back surfaces 206b, 208b and 210b of the micro light-emitting diodes 206, 208 and 210 connect to the adhesive layer 204. The contact pad 212p of the control device 212 and the electrodes 206p, 208p and 210p of the micro light-emitting diodes 206, 208 and 210 are located away from the carrier 200 and the adhesive layer 204. In some embodiments, the control device 212 and the micro light-emitting diodes 205 can be transferred onto the carrier 200 by mass transfer technologies such as stamp transferring and laser transferring.

Next, as shown in FIG. 17C, a coating process and a subsequent patterning process are performed to form the insulating layer 216 on the carrier 200. In some embodiments, insulating layer 216 surrounds and partially covers the control device 212 and the micro light-emitting diodes 206, 208 and 210. In addition, the insulating layer 216 has openings 216a, 216b, 216c and 216d to expose the contact pad 212p of the control device 212 and the electrodes 206p, 208p and 210p of the micro light-emitting diodes 206, 208 and 210, respectively.

Next, as shown in FIG. 17D, after the control device 212 and the micro light-emitting diodes 206, 208 and 210 are transferred onto the carrier 200, a plating process and a subsequent patterning process are performed to form the redistribution layer 220 on the control device 212 and the micro light-emitting diodes 206, 208 and 210. The redistribution layer 220 passes through the openings 216a, 216b, 216c and 216d of the insulating layer 216 (shown in FIG. 17C), and is electrically connected to the contact pad 212p of the control device 212 and the electrodes 206p, 208p, and 210p of the micro light-emitting diodes 206, 208 and 210, respectively. As shown in FIG. 17D, the control device 212 and the micro light-emitting diodes 206, 208 and 210 are disposed on the first side 220-1 of the redistribution layer 220.

Next, as shown in FIG. 17E, after the redistribution layer 220 is formed, a coating process and a subsequent patterning process are performed to form an insulating layer 222 covering the redistribution layer 220. The insulating layer 222 has an opening 222a exposing a portion of the redistribution layer 220 to define the formation position of the subsequent bonding pad.

Next, as shown in FIG. 17F, a plating process and a subsequent patterning process are performed to form bonding pads 224 on the insulating layer 222. The bonding pads 224 pass through the openings 222a of the insulating layer 222 (shown in FIG. 17E) and are electrically connected to the redistribution layer 220.

Next, as shown in FIG. 17G, an attaching process may be performed to attach a thin film layer 226 to the second side 220-2 of the redistribution layer 220 by a film-pasting machine. In some embodiments, the thin film layer 226 is in contact with the bonding pads 224 rather than the carrier 200. In some embodiments, the thin film layer 226 includes a structure formed by coating an adhesive layer on a substrate, such as UV tape. The material of the substrate includes epoxy, polyethylene terephthalate (PET), polyvinyl chloride (PVC), polyimide (PI), or a combination thereof.

Next, as shown in FIG. 17H, a removal process is performed to remove the carrier 200 from the adhesive layer 204. In some embodiments, the removal process includes laser debonding or another suitable removal process.

Next, as shown in FIG. 17I, another removal process is performed to remove the adhesive layer 204, so that the back surface 212b of the control device 212 and the back surfaces 206b, 208b, 210b of the micro light-emitting diodes 206, 208 and 210 are exposed from the insulating layer 216 to improve the light extraction efficiency of the micro light-emitting diode package structure. In some embodiments, the removal process includes chemical etching, plasma etching, or another suitable removal process.

Next, as shown in FIG. 17J, after removing the carrier 200 and the adhesive layer 204, a film pasting process or a coating process is performed to form the flexible material layer 250 covering the control device 212 and the micro light-emitting diodes 206, 208 and 210. In some embodiments, the flexible material layer 250 is in contact with the back surface 212b of the control device 212 and the back surfaces 206b, 208b and 210b of the micro light-emitting diodes 206, 208 and 210.

Next, as shown in FIG. 17K, a dicing process is performed to cut the flexible material layer 250 and the redistribution layer 220 along scribe lines 252L to form multiple discrete micro light-emitting diode package structures. In some embodiments, the cutting process includes laser cutting, dicing saw cutting, or another suitable dicing process. Finally, the thin film layer 226 is removed to form the micro light-emitting diode package structure 500a as shown in FIG. 1.

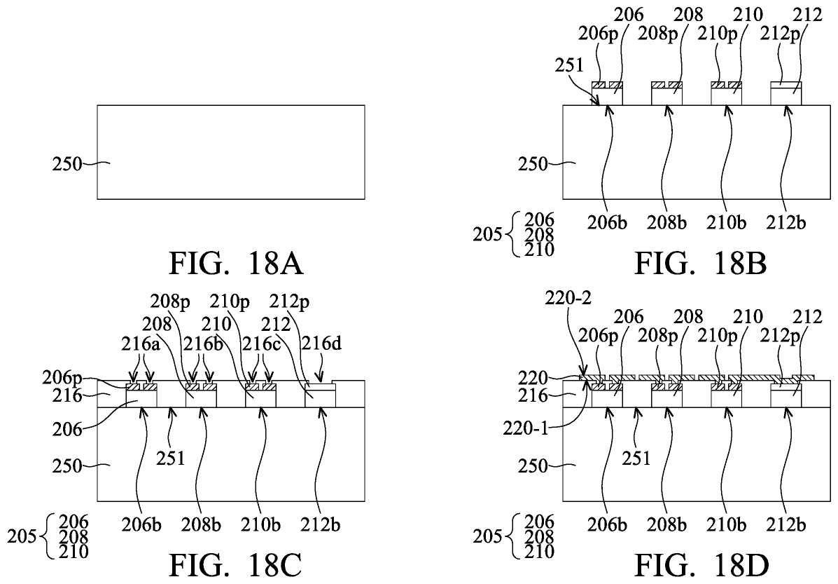

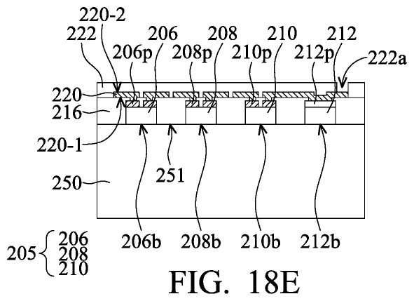

In some embodiments, the control device 212 and the micro light-emitting diodes 206, 208 and 210 may be disposed directly on the flexible material layer to form the micro light-emitting diode package structure 500a. FIGS. 18A-18E are schematic cross-sectional views at different stages of forming the micro light-emitting diode package structure 500a shown in FIG. 1 in accordance with some embodiments of the disclosure, and the reference numbers the same or similar as those previously described with reference to FIGS. 1-16 and 17A-17K denote the same or similar element.

As shown in FIG. 18A, first, a flexible material layer 250 is provided. Next, as shown in FIG. 18B, the control device 212 is disposed on the flexible material layer 250. In addition, light-emitting diodes 205 (including the micro light-emitting diodes 206, 208 and 210) are massively transferred onto the flexible material layer 250 so that the back surface 212b of the control device 212 and the back surfaces 206b, 208b and 210b of the micro light-emitting diodes 206, 208 and 210 are in contact with the flexible material layer 250. The interface 251 between the control device 212 and the micro light-emitting diodes 206, 208 and 210 and the flexible material layer 250 is located away from the contact pad 212p of the control device 212 and the electrodes 206p, 208p and 210p of the micro light-emitting diodes 206, 208 and 210.

Next, as shown in FIG. 18C, a coating process and a subsequent patterning process are performed to form the insulating layer 216 on the flexible material layer 250. The insulating layer 216 surrounds the control device 212 and the micro light-emitting diodes 206, 208 and 210. The openings 216a, 216b, 216c, 216d of the insulating layer 216 expose the contact pad 212p of the control device 212 and the electrodes 206p, 208p and 210p of the micro light-emitting diodes 206, 208 and 210, respectively.

Next, as shown in FIG. 18D, a plating process and a subsequent patterning process are performed to form the redistribution layer 220 on the control device 212 and the micro light-emitting diodes 206, 208, and 210. The redistribution layer 220 passes through the openings 216a, 216b, 216c and 216d of the insulating layer 216 (as shown in FIG. 18C), and is electrically connected to the contact pad 212p of the control device 212 and the electrodes 206p, 208p and 210p of the micro light-emitting diodes 206, 208 and 210, respectively.

As shown in FIG. 18E, after the redistribution layer 220 is formed, a coating process and a subsequent patterning process are performed to form the insulating layer 222 covering the redistribution layer 220. The insulating layer 222 has an opening 222a exposing a portion of the redistribution layer 220 to define the formation position of the subsequent bonding pad.

Next, as shown in FIG. 1, a plating process and a subsequent patterning process are performed to form bonding pads 224 passing through the insulating layer 222 and electrically connected to the redistribution layer 220. After performing the aforementioned processes, the micro light-emitting diode package structure 500a as shown in FIG. 1 is formed.

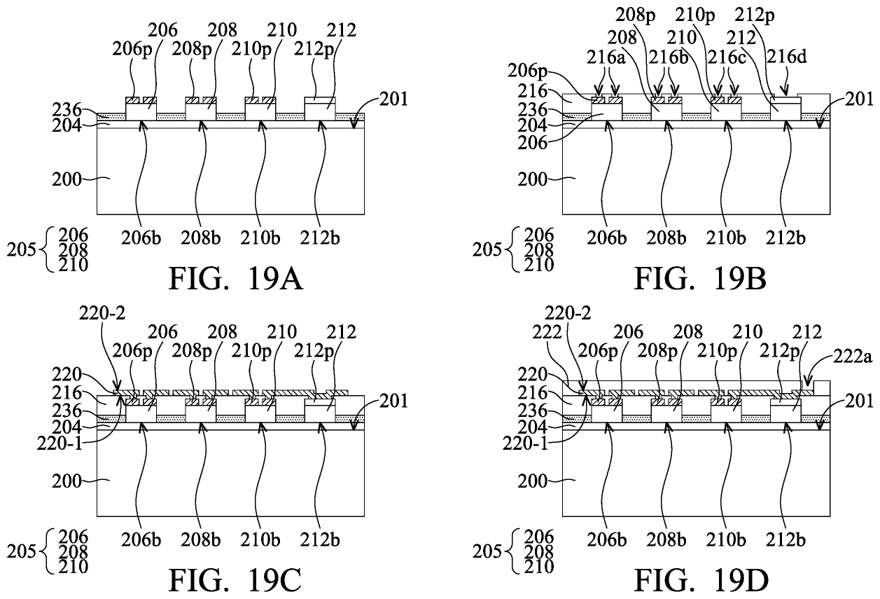

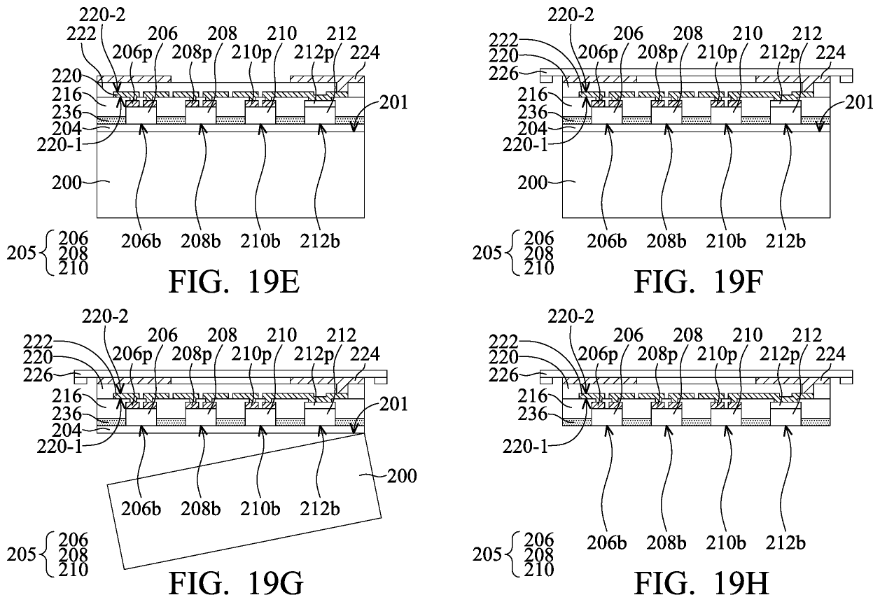

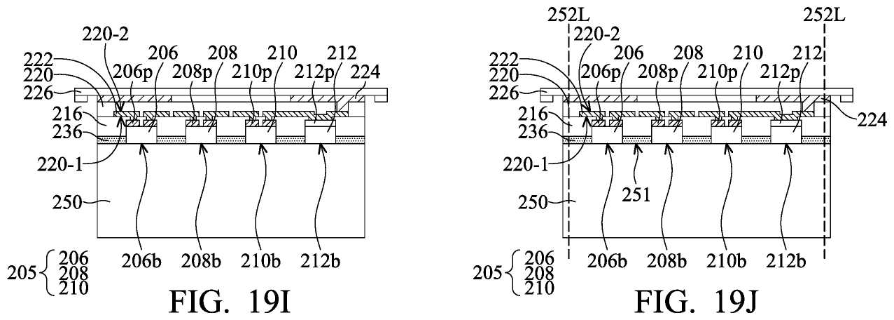

FIGS. 19A-19J are schematic cross-sectional views at different stages of forming the micro light-emitting diode package structure 500b shown in FIG. 2 in accordance with some embodiments of the disclosure, and the reference numbers the same or similar as those previously described with reference to FIGS. 1-16, 17A-17K and 18A-18E denote the same or similar element.

As shown in FIG. 19A, after performing the processes shown in FIGS. 17A and 17B (or performing the processes shown in FIG. 18A), the light-shielding layer 236 is formed on the carrier 200 by spin coating or mold casting, etc. The light shielding layer 236 surrounds the control device 212 and the micro light-emitting diodes 206, 208 and 210.

Next, as shown in FIG. 19B, processes similar to those shown in FIG. 17C are performed to form the insulating layer 216 on the light shielding layer 236. In some embodiments, the insulating layer 216 surrounds the control device 212 and the micro light-emitting diodes 206, 208 and 210 and covers the light shielding layer 236.

Next, as shown in FIGS. 19C-19G, processes similar to those shown in FIGS. 17D-17H are sequentially performed to form the redistribution layer 220 on the control device 212 and the micro light-emitting diodes 206, 208 and 210. Next, the insulating layer 222 is formed to cover the redistribution layer 220. The bonding pads 224 are then formed on the insulating layer 222 to be electrically connected to the redistribution layer 220. Next, the thin film layer 226 is attached to the second side 220-2 of the redistribution layer 220. Next, the carrier 200 is removed from the adhesive layer 204.

Next, as shown in FIG. 19H, processes similar to those shown in FIG. 171 are performed to remove the adhesive layer 204 so that the back surface 212b of the control device 212 and the back surfaces 206b, 208b and 210b of the micro light-emitting diodes 206, 208 and 210 are exposed from the light shielding layer 236.

Next, as shown in FIG. 191, processes similar to those shown in FIG. 17J are performed to form the flexible material layer 250 covering the light shielding layer 236, the back surface 212b of the control device 212 and the back surfaces 206b, 208b and 210b of the micro light-emitting diodes 206, 208 and 210.

Next, as shown in FIG. 19J, processes similar to those shown in FIG. 17K are performed to cut the light shielding layer 236, the flexible material layer 250 and the redistribution layer 220 along the scribe lines 252L to form discrete micro light-emitting diode package structures. Finally, the thin film layer 226 is removed to form the micro light-emitting diode package structure 500b as shown in FIG. 2. The light-shielding layer 236 of the micro light-emitting diode package structure 500b is formed before forming the insulating layer 216 and the redistribution layer 220. The light shielding layer 236 is formed between the redistribution layer 220 and the flexible material layer 250, and surrounds the control device 212 and the micro light-emitting diodes 206, 208 and 210.

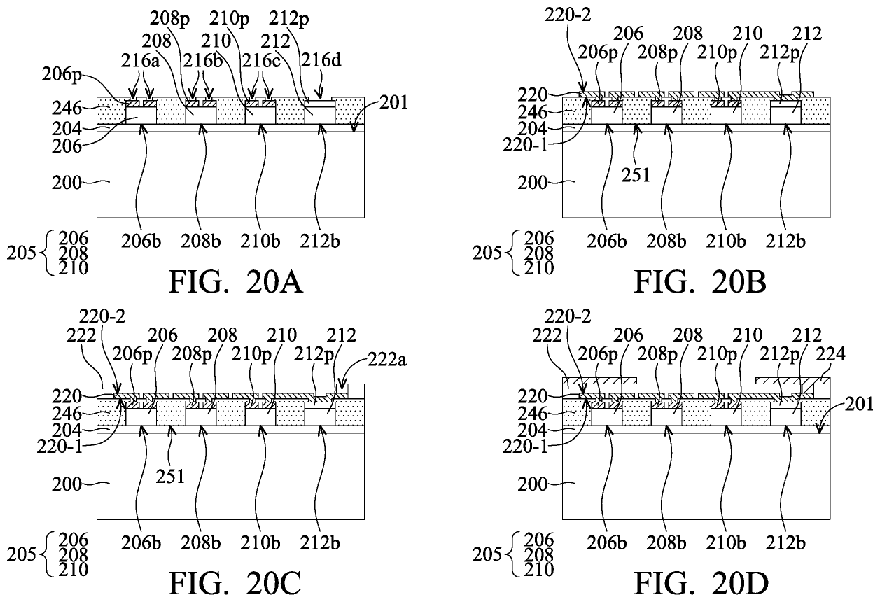

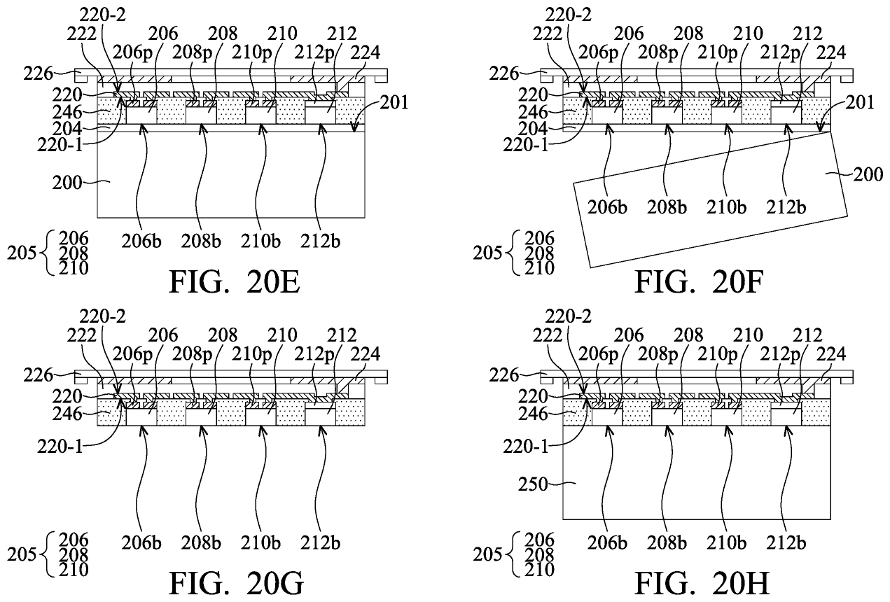

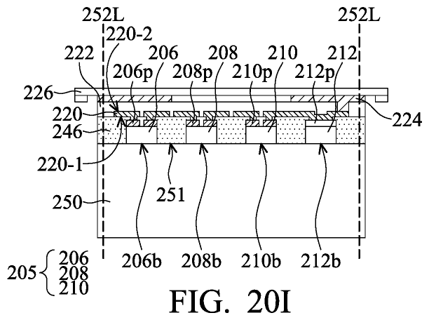

FIGS. 20A-201 are schematic cross-sectional views at different stages of forming the micro light-emitting diode package structure 500c in accordance with some embodiments of the disclosure, and the reference numbers the same or similar as those previously described with reference to FIGS. 1-16, 17A-17K, 18A-18E and 19A-19J denote the same or similar element.

As shown in FIG. 20A, after performing the processes shown in FIGS. 17A and 17B (or performing the processes shown in FIG. 18A), processes similar to those shown in FIG. 19A and subsequent patterning processes are performed to form a light shielding layer 246 on the carrier 200. The light-shielding layer 246 surrounds and partially covers the control device 212 and the micro light-emitting diodes 206, 208 and 210. In addition, the light shielding layer 246 has openings to expose the contact pads 212p of the control device 212 and the electrodes 206p, 208p and 210p of the micro light-emitting diodes 206, 208 and 210, respectively.

Next, as shown in FIG. 20B, processes similar to those shown in FIG. 17D are performed to form the redistribution layer 220 on the light shielding layer 246, the control device 212 and the micro light-emitting diodes 206, 208 and 210.

Next, as shown in FIGS. 20C-20F, processes similar to those shown in FIGS. 17E-17H are sequentially performed to form the insulating layer 222 to cover the redistribution layer 220. Next, the bonding pads 224 are formed on the insulating layer 222. Next, the thin film layer 226 is attached to the second side 220-2 of the redistribution layer 220. Next, the carrier 200 is removed from the adhesive layer 204.

Next, as shown in FIG. 20G, processes similar to those shown in FIG. 171 are performed to remove the adhesive layer 204 so that the back surface 212b of the control device 212 and the back surface 206b, 208b and 210b of the micro light-emitting diodes 206, 208 and 210 are exposed from the light shielding layer 246.

Next, as shown in FIG. 20H, processes similar to those shown in FIG. 17J are performed to form the flexible material layer 250 covering the light shielding layer 246, the back surface 212b of the control device 212 and the back surface 206b, 208b and 210b of the micro light-emitting diodes 206, 208 and 210.

Next, as shown in FIG. 201, processes similar to those shown in FIG. 17K are performed to cut the flexible material layer 250 and the redistribution layer 220 along the scribe lines 252L to form discrete micro light-emitting diode package structure. Finally, the thin film layer 226 is removed to form the micro light-emitting diode package structure 500c as shown in FIG. 3. The light-shielding layer 246 of the micro light-emitting diode package structure 500c is formed before forming the redistribution layer 220. The light shielding layer 246 is formed between the redistribution layer 220 and the flexible material layer 250, and surrounds the control device 212 and the micro light-emitting diodes 206, 208 and 210.

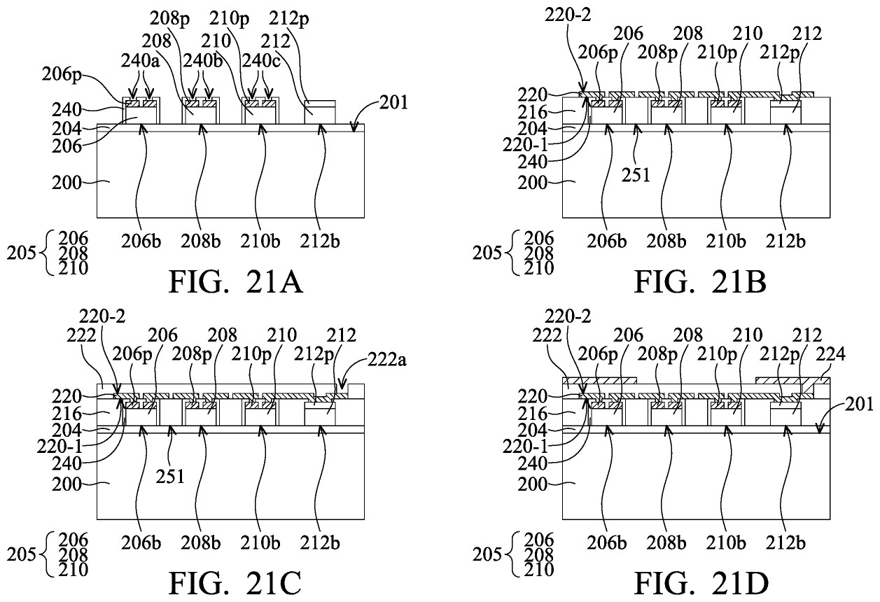

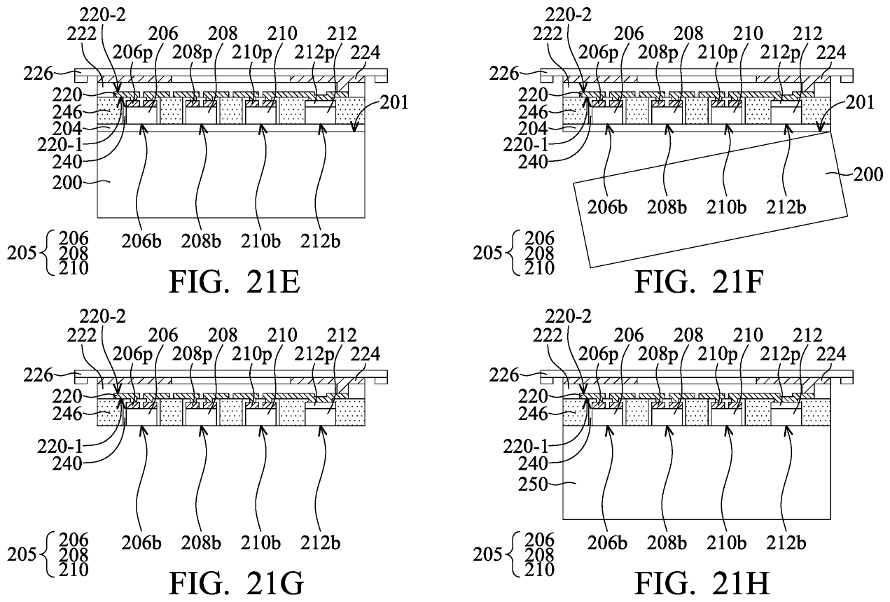

FIGS. 21A-211 are schematic cross-sectional views at different stages of forming the micro light-emitting diode package structure 500d shown in FIG. 4 in accordance with some embodiments of the disclosure, and the reference numbers the same or similar as those previously described with reference to FIGS. 1-16, 17A-17K, 18A-18E, 19A-19J and 20A-201 denote the same or similar elements.

As shown in FIG. 21A, after performing the processes shown in 17A and 17B (or performing the processes shown in 18A), a deposition process and subsequent patterning process are performed to form the distributed Bragg reflector layer 240 on the micro light-emitting diodes 206, 208 and 210. The distributed Bragg reflector layer 240 extends from the sidewalls of the micro light-emitting diodes 206, 208 and 210 to be close to the electrodes 206p, 208p and 210p. In addition, the distributed Bragg reflector layer 240 has openings 240a, 240b and 240c to expose the contact pad 212p of the control device 212 and the electrodes 206p, 208p and 210p of the micro light-emitting diodes 206, 208 and 210.

Next, as shown in FIG. 21B, the processes similar to those shown in FIGS. 17C and 17D are sequentially performed to form the insulating layer 216 on the carrier 200 and the distributed Bragg reflector layer 240 and surround the distributed Bragg reflector layer 240, the control device 212 and the micro light-emitting diodes 206, 208 and 210. In addition, the redistribution layer 220 is formed on the insulating layer 216, the distributed Bragg reflector layer 240, the control device 212 and the micro light-emitting diodes 206, 208 and 210. In addition, the redistribution layer 220 is in contact with the distributed Bragg reflector layer 240.

Next, as shown in FIGS. 21C to 21G, the processes similar to those shown in

FIGS. 17E-171 are sequentially performed to form the insulating layer 222 and the bonding pads 224 on the redistribution layer 220. Next, the thin film layer 226 is attached to the second side 220-2 of the redistribution layer 220. Next, the carrier 200 is removed from the adhesive layer 204. Next, the adhesive layer 204 is removed, so that the back surface 212b of the control device 212 and the back surfaces 206b, 208b and 210b of the micro light-emitting diodes 206, 208 and 210 are exposed from the insulating layer 216 and the distributed Bragg reflector layer 240.

Next, as shown in FIG. 21H, the processes similar to those shown in FIG. 17J are performed to form the flexible material layer 250 covering the distributed Bragg reflector layer 240, the back surface 212b of the control device 212 and the back surfaces 206b, 208b and 210b of the micro light-emitting diodes 206, 208 and 210.

Next, as shown in FIG. 211, the processes similar to those shown in FIG. 17K are performed to cut the flexible material layer 250 and the redistribution layer 220 along the scribe lines 252L to form multiple discrete micro light-emitting diode package structures. Finally, the thin film layer 226 is removed to form the micro light-emitting diode package structure 500d as shown in FIG. 4. The distributed Bragg reflector layer 240 of the micro light-emitting diode package structure 500d is formed before forming the redistribution layer 220. The distributed Bragg reflector layer 240 is formed between the redistribution layer 220 and the flexible material layer 250, and surrounds the control device 212 and the micro light-emitting diodes 206, 208 and 210.

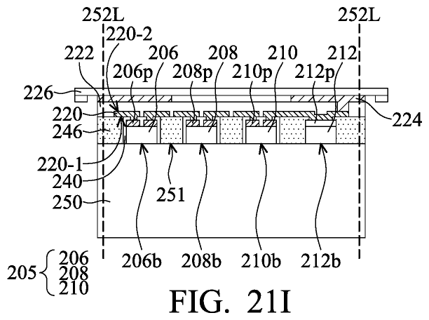

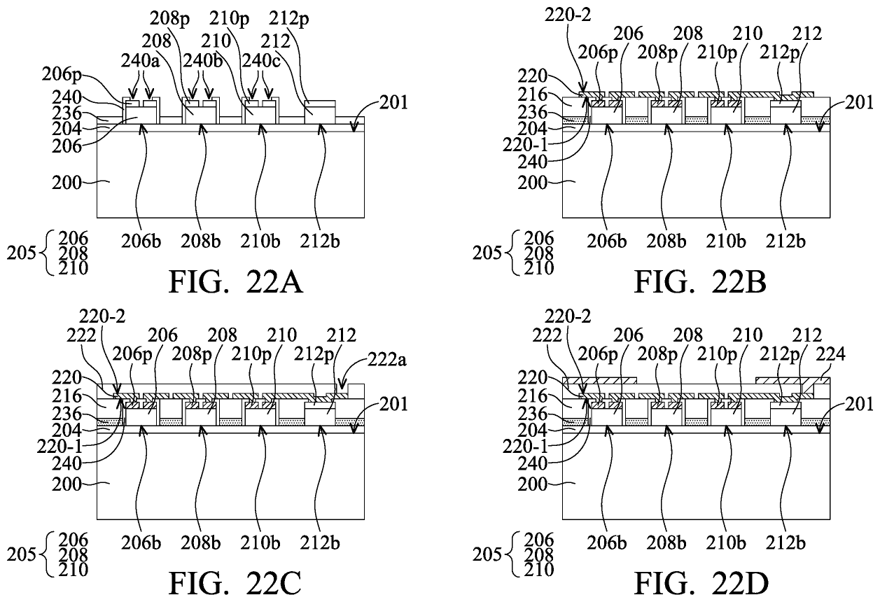

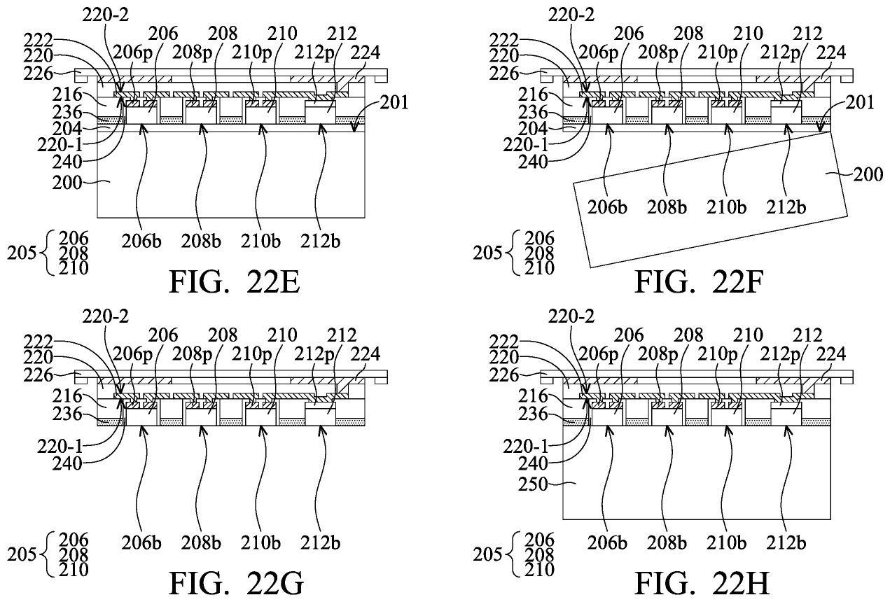

FIGS. 22A-221 are schematic cross-sectional views at different stages of forming the micro light-emitting diode package structure 500e shown in FIG. 5 in accordance with some embodiments of the disclosure, and the reference numbers the same or similar as those previously described with reference to FIGS. 1-16, 17A-17K, 18A-18E, 19A-19J, 20A-201 and 21A-211 denote the same or similar elements.

As shown in FIG. 22A, after the processes shown in FIGS. 17A and 17B (or the processes shown in FIG. 18A) are sequentially performed, the processes shown in FIG. 21A are performed to form the distributed Bragg reflector layer 240 on the micro light-emitting diodes 206, 208 and 210. Next, the processes shown in FIG. 19A are performed to form the light shielding layer 236 on the carrier 200, and surrounds the distributed Bragg reflector layer 240, the control device 212 and the micro light-emitting diodes 206, 208 and 210.

Next, as shown in FIGS. 22B-22G, the processes similar to those shown in FIGS. 17C-171 are sequentially performed to form the insulating layer 216 on the light shielding layer 236 and the distributed Bragg reflector layer 240. Next, the redistribution layer 220 is formed on the insulating layer 216. Next, the insulating layer 222 and the bonding pads 224 are sequentially formed on the redistribution layer 220. Next, the thin film layer 226 is attached onto the second side 220-2 of the redistribution layer 220. Next, the carrier 200 is removed from the adhesive layer 204. The adhesive layer 204 is then removed so that the back surface 212b of the control device 212 and the back surfaces 206b, 208b and 210b of the micro light-emitting diodes 206, 208 and 210 are exposed from the light shielding layer 236 and the distributed Bragg reflector layer 240.

Next, as shown in FIG. 22H, the processes similar to those shown in FIG. 17J are performed to form the flexible material layer 250 covering the light shielding layer 236, the distributed Bragg reflector layer 240, and the back surface 212b of the control device 212 and the back surfaces 206b, 208b and 210b of the micro light-emitting diodes 206, 208 and 210.

Next, as shown in FIG. 221, the processes similar to those shown in FIG. 17K are performed to cut the light shielding layer 236, the flexible material layer 250 and the redistribution layer 220 along the scribe lines 252L to form discrete micro light-emitting diode package structures. Finally, the thin film layer 226 is removed to form the micro light-emitting diode package structure 500e as shown in FIG. 5. The light shielding layer 236 and the distributed Bragg reflector layer 240 of the micro light-emitting diode package structure 500e are formed before forming the redistribution layer 220. The light shielding layer 236 and the distributed Bragg reflector layer 240 are formed between redistribution layer 220 and flexible material layer 250, and surround the control device 212 and micro light-emitting diodes 206, 208 and 210.

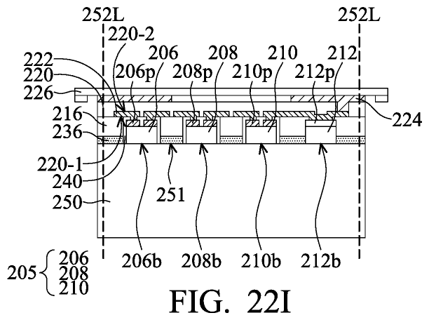

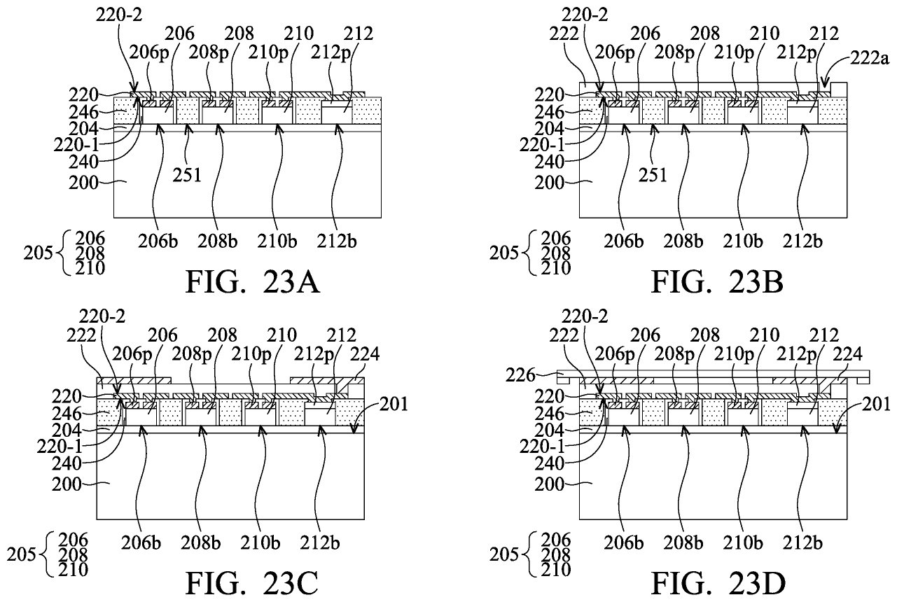

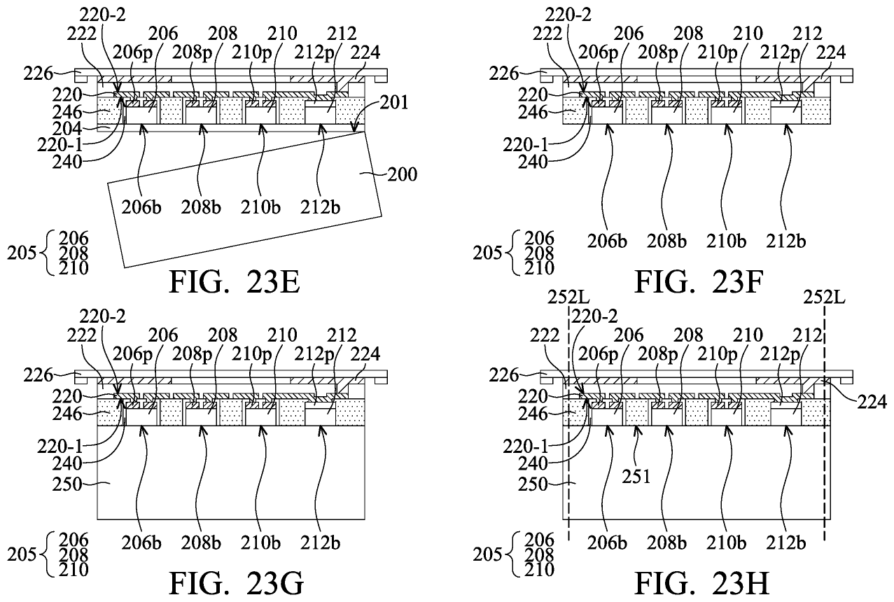

FIGS. 23A-23H are schematic cross-sectional views at different stages of forming the micro light-emitting diode package structure 500f shown in FIG. 6 in accordance with some embodiments of the disclosure, and the reference numbers the same or similar as those previously described with reference to FIGS. 1-16, 17A-17K, 18A-18E, 19A-19J, 20A-201, 21A-211 and 22A-221 denote the same or similar elements.

As shown in FIG. 23A, the processes shown in FIGS. 17A and 17B (or the processes shown in FIG. 18A) are sequentially performed. Next, the processes shown in FIG. 21A are performed. After performing the processes shown in FIG. 21A, the processes shown in FIG. 20A are performed to form the light shielding layer 246 on the carrier 200. The light-shielding layer 246 surrounds the distributed Bragg reflector layer 240, the control device 212 and the micro light-emitting diodes 206, 208 and 210. Next, processes similar to those shown in FIG. 17D are performed to form the redistribution layer 220 on the light shielding layer 246, the distributed Bragg reflector layer 240, the control device 212 and the micro light-emitting diodes 206, 208 and 210.

Next, as shown in FIGS. 23B-23F, the processes similar to those shown in FIGS. 17E-171 are sequentially performed to form the insulating layer 222 and the bonding pads 224 on the redistribution layer 220. Next, the thin film layer 226 is attached onto the second side 220-2 of the redistribution layer 220. Next, the carrier 200 is removed from the adhesive layer 204. Next, the adhesive layer 204 is removed so that the back surface 212b of the control device 212 and the back surfaces 206b, 208b and 210b of the micro light-emitting diodes 206, 208 and 210 are exposed from the light shielding layer 246 and the distributed Bragg reflector layer 240.

Next, as shown in FIG. 23G, the processes similar to those shown in FIG. 17J are performed to form the flexible material layer 250 covering the light shielding layer 246, the distributed Bragg reflector layer 240, the back surface 212b of the control device 212 and the back surfaces 206b, 208b and 210b of the micro light-emitting diodes 206, 208 and 210.

Next, as shown in FIG. 23H, the processes similar to those shown in FIG. 17K are performed to cut the light shielding layer 246, the flexible material layer 250 and the redistribution layer 220 along the scribe lines 252L to form discrete micro light-emitting diode package structures. Finally, the thin film layer 226 is removed to form the micro light-emitting diode package structure 500f as shown in FIG. 6. The light shielding layer 246 and the distributed Bragg reflector layer 240 of the micro light-emitting diode package structure 500f are formed before the redistribution layer 220 is formed. The light shielding layer 246 and the distributed Bragg reflector layer 240 are formed between the redistribution layer 220 and the flexible material layer 250 and surround the control device 212 and the micro light-emitting diodes 206, 208 and 210.

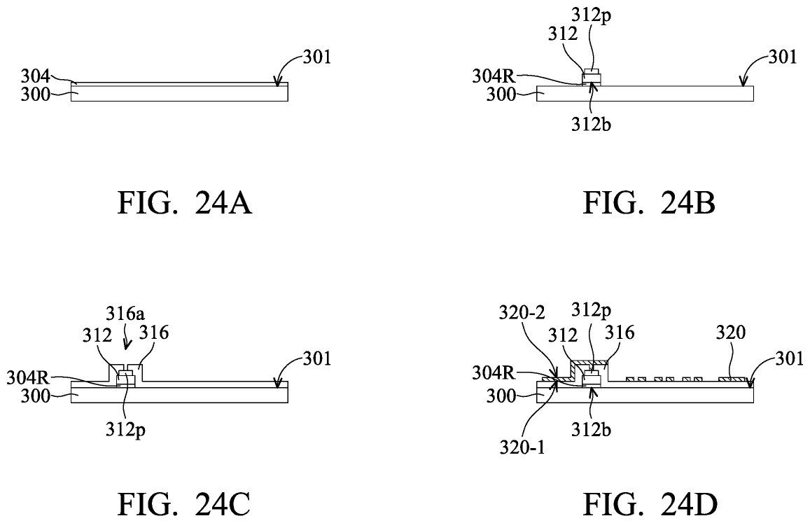

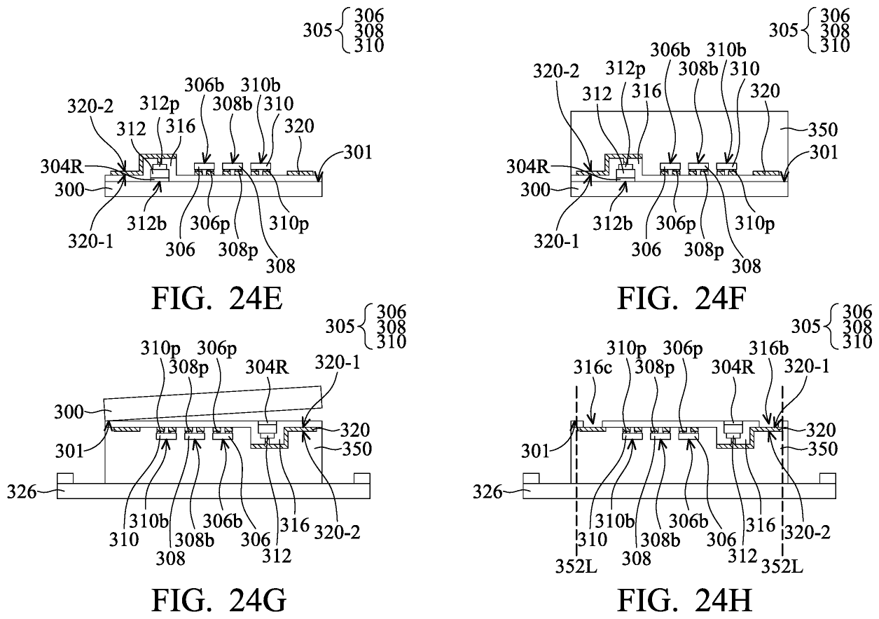

FIGS. 24A-24H are schematic cross-sectional views at different stages of forming the micro light-emitting diode package structure 500g shown in FIG. 7 in accordance with some embodiments of the disclosure, and the reference numbers the same or similar as those previously described with reference to FIGS. 1-16, 17A-17K, 18A-18E, 19A-19J, 20A-201, 21A-211, 22A-221 and 23A-23H denote the same or similar elements.

As shown in FIG. 24A, first, a carrier 300 is provided. In some embodiments, the carrier 200 and the carrier 300 comprise the same or similar materials. Next, an adhesive layer 304 is coated on a surface 301 of the carrier 300. In some embodiments, the adhesive layers 204 and 304 comprise the same or similar materials.

Next, as shown in FIG. 24B, the control device 312 can be disposed on the carrier by mass transfer technologies such as stamp transferring or laser transferring. Next, a removal process is performed to remove the adhesive layer 304 not covered by the control device 312. The remaining adhesive layer between the back surface 312b of the control device 312 and the carrier 300 is denoted as an adhesive layer 304R. In some embodiments, the removal process includes chemical etching, plasma etching, or another suitable removal process.

Next, as shown in FIG. 24C, after disposing the control device 312 on the carrier 300, a coating process and a subsequent patterning process are performed to form the insulating layer 316 covering the carrier 300 and the control device 312. The insulating layer 316 may conformally cover and surround the control device 312. In addition, the insulating layer 316 has an opening 316a to expose the contact pad 312p of the control device 312.

Next, as shown in FIG. 24D, after disposing the control device 312 on the carrier 300, a plating process and a subsequent patterning process are performed to form the redistribution layer 320 on the control device 312. The redistribution layer 320 partially covers the insulating layer 316, and passes through the opening 316a (FIG. 24C) of the insulating layer 316 to be electrically connected to the contact pad 312p of the control device 312. As shown in FIG. 24D, the control device 312 is disposed on the first side 320-1 of the redistribution layer 320.

Next, as shown in FIG. 24E, after the redistribution layer 320 is formed, the micro light-emitting diodes 305 (including the micro light-emitting diodes 306, 308 and 310) are transferred onto the surface 301 of the carrier 300. The control device 312 and the micro light-emitting diodes 305 are disposed side by side. In addition, the micro light-emitting diodes 305 are disposed on the second side 320-2 of the redistribution layer 320. As shown in FIG. 24E, the electrodes 306p, 308p, and 310p of the micro light-emitting diodes 306, 308, and 310 are electrically connected to the redistribution layer 320. In addition, the contact pads 312p of the control device 312 and the back surfaces 306b, 308b and 310b of the micro light-emitting diodes 306, 308 and 310 are located away from the carrier 300. In some embodiments, the micro light-emitting diodes 205 and 305 have the same or similar configuration and transferring method.

Next, as shown in FIG. 24F, a film pasting or a coating process is performed to form the flexible material layer 350 covering the control device 312 and the micro light-emitting diodes 306, 308, and 310. In some embodiments, the flexible material layer 350 is in contact with the back surface 306b, 308b and 310b of the micro light-emitting diodes 306, 308 and 310, and separated from the control device 312 by the insulating layer 316 and the redistribution layer 320.

Next, as shown in FIG. 24G, the thin film layer 326 can be attached to the second side 320-2 of the redistribution layer 320 by performing an attaching process by using a film-pasting machine. In some embodiments, the thin film layer 326 is in contact with the flexible material layer 350 rather than the carrier 300. In some embodiments, the thin film layers 226 and 326 have the same or similar materials. Next, a removal process is performed to remove the carrier 300 from the adhesive layer 304R. In some embodiments, the removal process includes laser debonding or another suitable removal process.

Next, as shown in FIG. 24H, a patterning process is performed on the insulating layer 316 to form openings 316b and 316c in the insulating layer 316 that expose portions of the redistribution layer 320, so that the redistribution layer 320 can be electrically connected to external circuits. Then, a dicing process is performed to cut the flexible material layer 350 and the redistribution layer 320 along the scribe lines 352L to form multiple discrete micro light-emitting diode package structures. In some embodiments, the dicing process includes laser cutting, dicing saw cutting, or another suitable dicing process. Finally, the thin film layer 326 is removed to form the micro light-emitting diode package structure 500g as shown in FIG. 7. Compared with the micro light-emitting diode package structures 500a-500f, the method for forming the micro light-emitting diode package structure 500g includes forming the redistribution layer 320 after disposing the control device 312 on the carrier 300. After the redistribution layer 320 is formed, the micro light-emitting diodes 305 are transferred onto the carrier 300. The insulating layer 316 is formed to cover the carrier 300 and the control device 312 before forming the redistribution layer 320. In addition, the flexible material layer 350 is formed before removing the carrier 300.

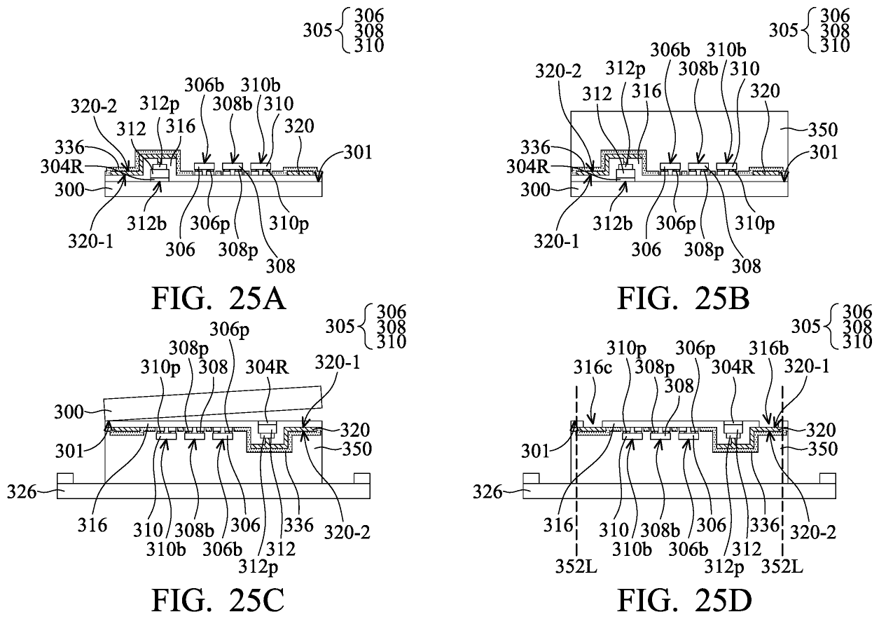

FIGS. 25A-25D are schematic cross-sectional views at different stages of forming the micro light-emitting diode package structure 500h shown in FIG. 8 in accordance with some embodiments of the disclosure, and the reference numbers the same or similar as those previously described with reference to FIGS. 1-16, 17A-17K, 18A-18E, 19A-19J, 20A-201, 21A-211, 22A-221, 23A-23H and 24A-24H denote the same or similar elements.

As shown in FIG. 25A, after sequentially performing processes similar to those shown in FIGS. 24A-24E, a coating process is performed to form the light shielding layer 336 conformally covering the redistribution layer 320 and surrounding the micro light-emitting diodes 306, 308 and 310.

Next, as shown in FIGS. 25B-25D, the processes similar to those shown in FIGS. 24F-24H are sequentially performed to form the flexible material layer 350 covering the light shielding layer 336, the control device 312 and the micro light-emitting diodes 306, 308 and 310. Next, the thin film layer 326 is attached to the second side 320-2 of the redistribution layer 320. Next, the carrier 300 is removed from the adhesive layer 304R. Next, the flexible material layer 350 and redistribution layer 320 are cut along the scribe lines 352L to form multiple discrete micro light-emitting diode package structures. Finally, the thin film layer 326 is removed to form the micro light-emitting diode package structure 500h as shown in FIG. 8. Compared with the micro light-emitting diode package structure 500g, the light-shielding layer 336 of the micro light-emitting diode package structure 500h is formed after forming the redistribution layer 320 and massively transferring the micro light-emitting diodes 305 onto the carrier 300. The light shielding layer 336 is formed between the redistribution layer 320 and the flexible material layer 350, and surrounds the micro light-emitting diodes 305.

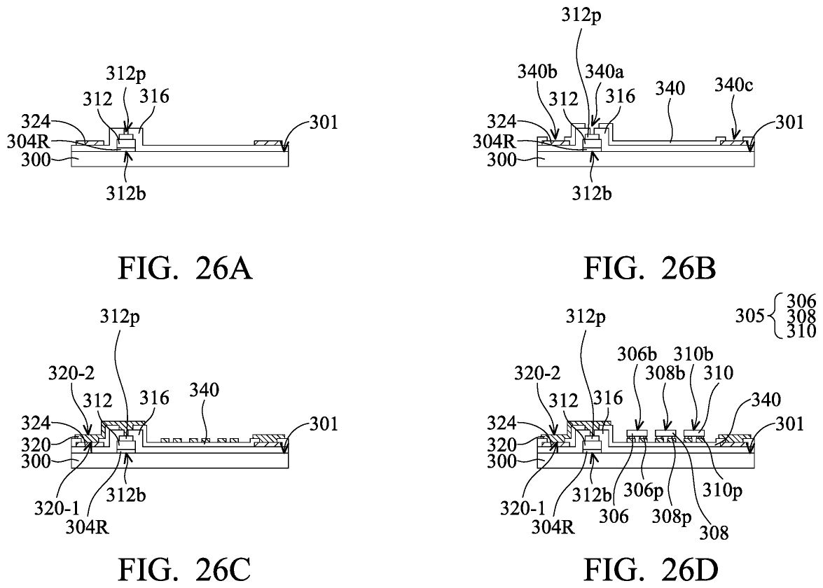

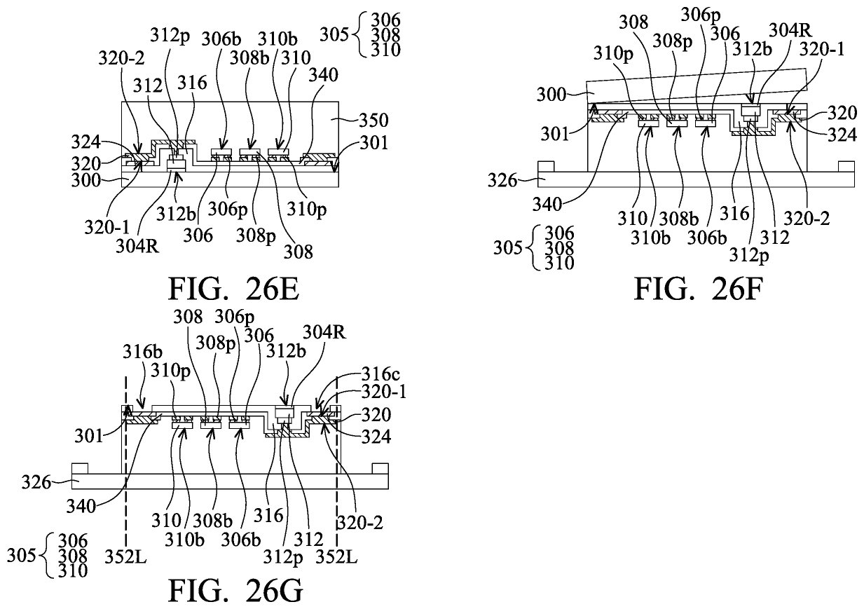

FIGS. 26A-26G are schematic cross-sectional views at different stages of forming the micro light-emitting diode package structure 500i shown in FIG. 9 in accordance with some embodiments of the disclosure, and the reference numbers the same or similar as those previously described with reference to FIGS. 1-16, 17A-17K, 18A-18E, 19A-19J, 20A-201, 21A-211, 22A-221, 23A-23H, 24A-24H and 25A-25D denote the same or similar elements.

As shown in FIG. 26A, after sequentially performing processes similar to those shown in FIGS. 24A to 24C, a plating process is performed to form the bonding pads 324 on the insulating layer 316. The bonding pads 324 can electrically connect to the redistribution layer 320 subsequently formed thereon to external circuits.

Next, as shown in FIG. 26B, a deposition process and a subsequent patterning process are performed to form the distributed Bragg reflector layer 340 on the insulating layer 316. In addition, the distributed Bragg reflector layer 340 has openings 340a, 340b and 340c to expose the contact pad 312p of the control device 312 and the bonding pads 324, respectively.

Next, as shown in FIGS. 26C-26G, process similar to those shown in FIGS. 24D-24H are sequentially performed to form the redistribution layer 320 on the distributed Bragg reflector layer 340 and the control device 312. Next, the micro light-emitting diodes 305 are transferred onto the carrier 320. Next, the flexible material layer 350 is formed to cover the distributed Bragg reflector layer 340, the control device 312 and the micro light-emitting diodes 306, 308 and 310. Next, the thin film layer 326 is attached to the second side 320-2 of the redistribution layer 320. Next, the adhesive layer 304R is removed from the carrier 300. Next, the flexible material layer 350 and the redistribution circuit layer 320 are cut along the scribe lines 352L to form multiple discrete micro light-emitting diode package structures. Finally, the thin film layer 326 is removed to form the micro light-emitting diode package structure 500i as shown in FIG. 9. Compared with the micro light-emitting diode package structure 500g, the distributed Bragg reflector layer 340 of the micro light-emitting diode package structure 500i adjacent to the electrodes 306p, 308p and 310p of the micro light-emitting diodes 306, 308 and 310 is formed before forming the redistribution layer 320. In addition, the redistribution layer 320 is in contact with the distributed Bragg reflector layer 340.

FIGS. 27A-27D are schematic cross-sectional views at different stages of forming the micro light-emitting diode package structure 500k shown in FIG. 10 in accordance with some embodiments of the disclosure, and the reference numbers the same or similar as those previously described with reference to FIGS. 1-16, 17A-17K, 18A-18E, 19A-19J, 20A-201, 21A-211, 22A-221, 23A-23H, 24A-24H, 25A-25D and 26A-26G denote the same or similar elements.

As shown in FIG. 27A, after the processes similar to those shown in FIGS. 24A-24C and FIGS. 26A-26D are sequentially performed, processes similar to those shown in FIG. 25A are performed to form the light shielding layer 336 conformally covering the redistribution layer 320 and the distributed Bragg reflector layer 340, and surrounds the micro light-emitting diodes 306, 308 and 310.

Next, as shown in FIGS. 27B-27D, the processes similar to those shown in FIGS. 24F -24H are sequentially performed to form the flexible material layer 350 covering the light-shielding layer 336, the distributed Bragg reflector layer 340, the control device 312 and the micro light-emitting diodes 306, 308 and 310. Next, the thin film layer 326 is attached to the second side 320-2 of the redistribution layer 320. Next, the carrier 300 is removed from the adhesive layer 304R. Next, the light shielding layer 336, the distributed Bragg reflector layer 340, the flexible material layer 350 and the redistribution layer 320 are cut along the scribe lines 352L to form multiple discrete micro light-emitting diode package structures. Finally, the thin film layer 326 is removed to form the micro light-emitting diode package structure 500k as shown in FIG. 10. Compared with the micro light-emitting diode package structure 500g, the distributed Bragg reflector layer 340 of the micro light-emitting diode package structure 500k is formed before forming the redistribution layer 320. In addition, the light shielding layer 336 is formed after forming the redistribution layer 320 and massively transferring the micro light-emitting diodes 305 onto the carrier 300.

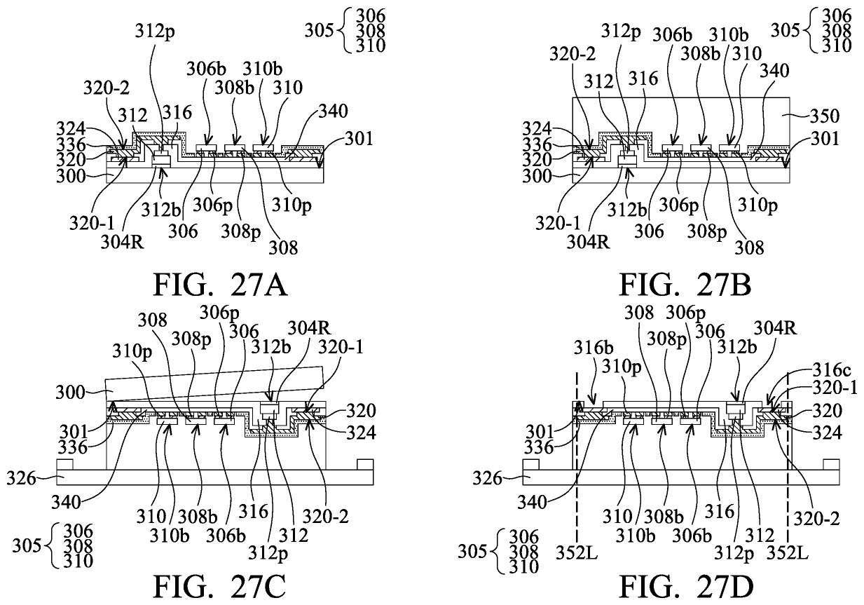

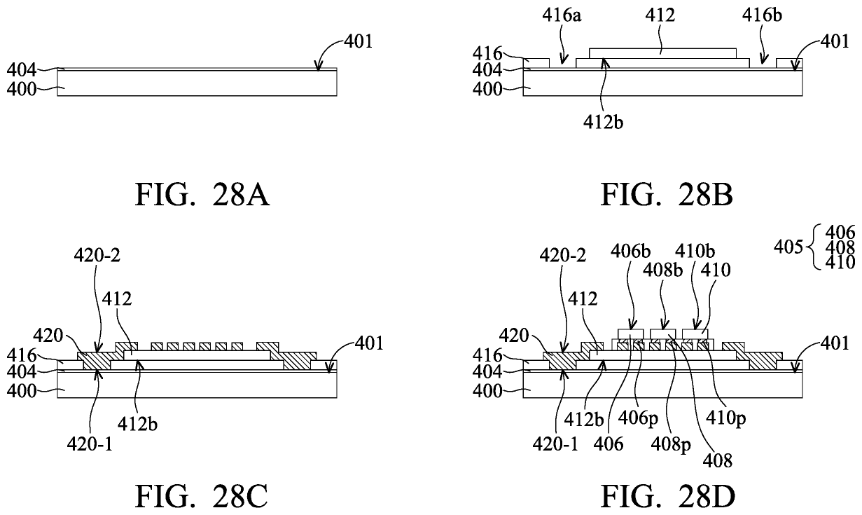

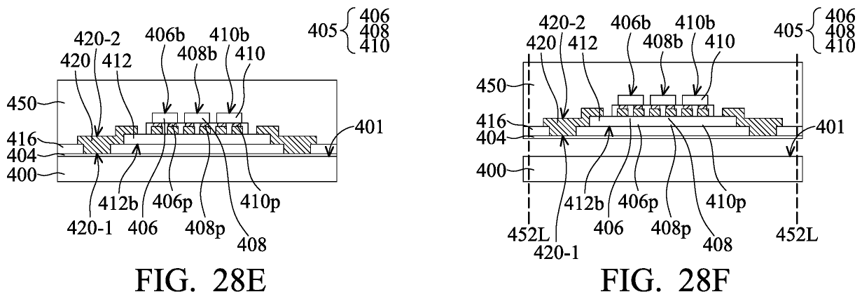

FIGS. 28A-28F are schematic cross-sectional views at different stages of the micro light-emitting diode package structure 5001 shown in FIG. 11 in accordance with some embodiments of the disclosure, and the reference numbers the same or similar as those previously described with reference to FIGS. 1-16, 17A-17K, 18A-18E, 19A-19J, 20A-201, 21A-211, 22A-221, 23A-23H, 24A-24H, 25A-25D, 26A-26G and 27A-27D denote the same or similar elements.

As shown in FIG. 28A, first, a carrier 400 is provided. In some embodiments, the carriers 200, 300 and 400 comprise the same or similar materials. Next, an adhesive layer 404 is coated on a surface 401 of the carrier 400. In some embodiments, the adhesive layers 204, 304 and 404 comprise the same or similar materials. In some embodiments, the carrier 400 may be not coated with the adhesive layer 404 thereon.

Next, as shown in FIG. 28B, a coating process and a subsequent patterning process are performed to form the insulating layer 416 covering the surface 401 of the carrier 400. The insulating layer 416 serves as a support layer for the control device 412, and has openings 416a and 416b to define the connection portions of the redistribution layer 420 subsequently formed thereon to the external circuit. After the insulating layer 416 is formed, the control device 412 is disposed on the insulating layer 416. In some embodiments, the back surface 412b of the control device 412 is in contact with the insulating layer 416.

Next, as shown in FIG. 28C, after disposing the control device 412 on the carrier 400, a plating process and a subsequent patterning process are performed to form the redistribution layer 420 on the control device 412. The redistribution layer 420 partially covers the insulating layer 416, and passes through the openings 416a and 416b of the insulating layer 416 (shown in FIG. 28B) to be electrically connected to the control device 412. As shown in FIG. 28C, the control device 412 is disposed on the first side 420-1 of the redistribution layer 420.

Next, as shown in FIG. 28D, after the redistribution layer 420 is formed, the micro light-emitting diodes 405 (including the micro light-emitting diodes 406, 408, and 410) are massively transferred directly above the control device 412. In addition, the micro light-emitting diodes 405 are disposed on the second side 420-1 of the redistribution layer 420. As shown in FIG. 28D, the electrodes 406p, 408p, and 410p of the micro light-emitting diodes 406, 408, and 410 are electrically connected to the redistribution layer 420.

In addition, the back surfaces 406b, 408b, 410b of the micro light-emitting diodes 406, 408 and 410 are located away from the carrier 400. In some embodiments, the micro light-emitting diodes 205, 305 and 405 have the same or similar configuration and transferring method.

Next, as shown in FIG. 28E, a film pasting or coating process is performed to form the flexible material layer 450 covering the control device 412 and the micro light-emitting diodes 406, 408, and 410. In some embodiments, the flexible material layer 450 is in contact with the back surfaces 406b, 408b, 410b of the micro light-emitting diodes 406, 408 and 410, and separated from the control device 412 by the redistribution layer 420.

Next, as shown in FIG. 28F, a removal process is performed to remove the carrier 400 from the adhesive layer 404. In some embodiments, the removal process includes laser debonding or another suitable removal process. Next, a dicing process is performed to cut the flexible material layer 450 and the redistribution layer 420 along the scribe lines 452L to form multiple discrete micro light-emitting diode package structures. In some embodiments, the dicing process includes laser cutting, dicing saw cutting, or another suitable dicing process. Finally, the micro light-emitting diode package structure 5001 as shown in FIG. 11 is formed. Compared with the micro light-emitting diode package structures 500a-500i and 500k, the method for forming the micro light-emitting diode package structure 5001 includes forming the redistribution layer 420 after disposing the control device 412 on the carrier 400. In addition, the micro light-emitting diode 405 is transferred to directly above the control device 412 after the redistribution layer 420 is formed. Furthermore, the insulating layer 416 is formed to cover the carrier 400 before disposing the control devices 412. Moreover, the flexible material layer 450 of is formed before removing the carrier 400.

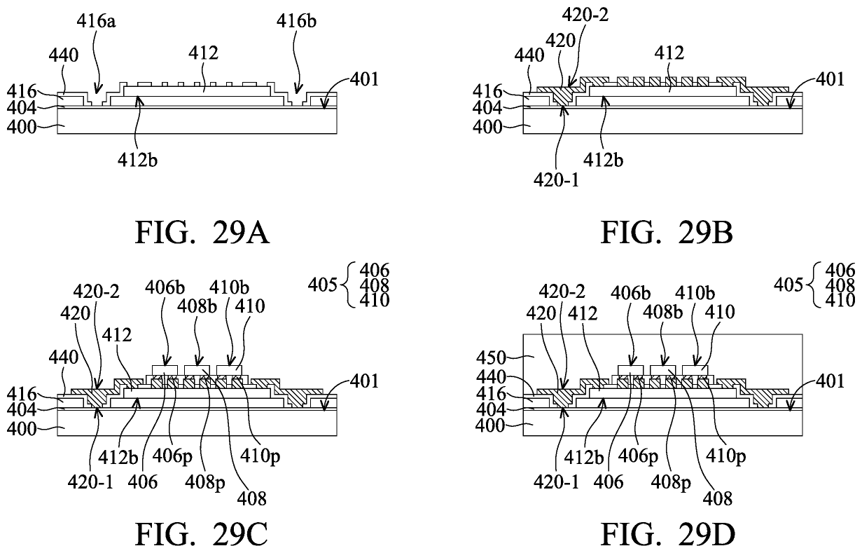

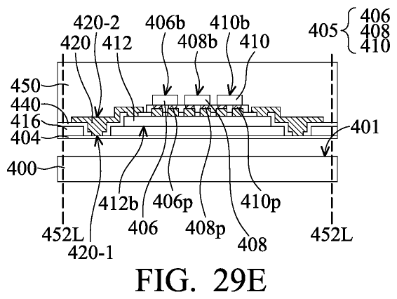

FIGS. 29A-29E are schematic cross-sectional views at different stages of forming the micro light-emitting diode package structure 500m shown in FIG. 12 in accordance with some embodiments of the disclosure, and the reference numbers the same or similar as those previously described with reference to FIGS. 1-16, 17A-17K, 18A-18E, 19A-19J, 20A-201, 21A-211, 22A-221, 23A-23H, 24A-24H, 25A-25D, 26A-26G, 27A-27D and 28A-28F denote the same or similar elements.

As shown in FIG. 29A, after the processes similar to those shown in FIGS. 28A and 28B are sequentially performed, a deposition process and a subsequent patterning process are performed to form the distributed Bragg reflector layer 440 on the insulating layer 416. In addition, the distributed Bragg reflector layer 440 has openings corresponding to the openings 416a and 416b and the positions of the electrodes of the micro light-emitting diodes 405 subsequently transferred thereon. Therefore, the subsequently formed redistribution layer 420 may pass through the openings to electrically connect the control device 412 and the micro light-emitting diodes 405 to the external circuits.

Next, as shown in FIGS. 29B-29E, processes similar to those shown in FIGS. 28C-28F are sequentially performed to form the redistribution layer 420 on the distributed Bragg reflector layer 440 and the control device 412. Next, the micro light-emitting diodes 405 (including the micro light-emitting diodes 406, 408 and 410) are massively transferred directly above the control device 412. Next, the flexible material layer 450 is formed to cover the distributed Bragg reflection layer 440, the control device 412 and the micro light-emitting diodes 406, 408 and 410. Next, the carrier 400 is removed from the adhesive layer 404. Next, the distributed Bragg reflector layer 440, the flexible material layer 450 and the redistribution layer 420 are cut along the scribe lines 452L. Finally, the micro light-emitting diode package structure 500m as shown in FIG. 12 is formed. Compared with the micro light-emitting diode package structure 5001, the distributed Bragg reflector layer 440 of the micro light-emitting diode package structure 500m close to the electrodes 406p, 408p and 410p of the micro light-emitting diodes 406, 408, and 410 is formed before forming the redistribution layer 420. In addition, the redistribution layer 420 is in contact with the distributed Bragg reflector layer 440.

FIGS. 30A-30C are schematic cross-sectional views at different stages of forming the micro light-emitting diode package structure 500n shown in FIG. 13 in accordance with some embodiments of the disclosure, and the reference numbers the same or similar as those previously described with reference to FIGS. 1-16, 17A-17K, 18A-18E, 19A-19J, 20A-201, 21A-211, 22A-221, 23A-23H, 24A-24H, 25A-25D, 26A-26G, 27A-27D, 28A-28F and 29A-29E denote the same or similar elements.

As shown in FIG. 30A, after sequentially performing processes similar to those shown in FIGS. 28A-28D, a coating process is performed to form the light shielding layer 436 conformally covering the redistribution layer 420 and the control device 412, and surrounding the micro light-emitting diodes 406, 408 and 410.

Next, as shown in FIGS. 30B and 30C, processes similar to those shown in FIGS. 28E and 28F is sequentially performed to form the flexible material layer 450 covering the light shielding layer 436, the control device 412 and the micro light-emitting diodes 406, 408 and 410. Next, the carrier 400 is removed from the adhesive layer 404. Next, the light shielding layer 436, the flexible material layer 450 and the redistribution layer 420 are cut along the scribe lines 452L. Finally, the micro light-emitting diode package structure 500n as shown in FIG. 13 is formed. Compared with the micro light-emitting diode package structure 5001, the light shielding layer 436 of the micro light-emitting diode package structure 500n is formed after forming the redistribution layer 420 and after massively transferring the micro light-emitting diodes 405 onto the carrier 400.

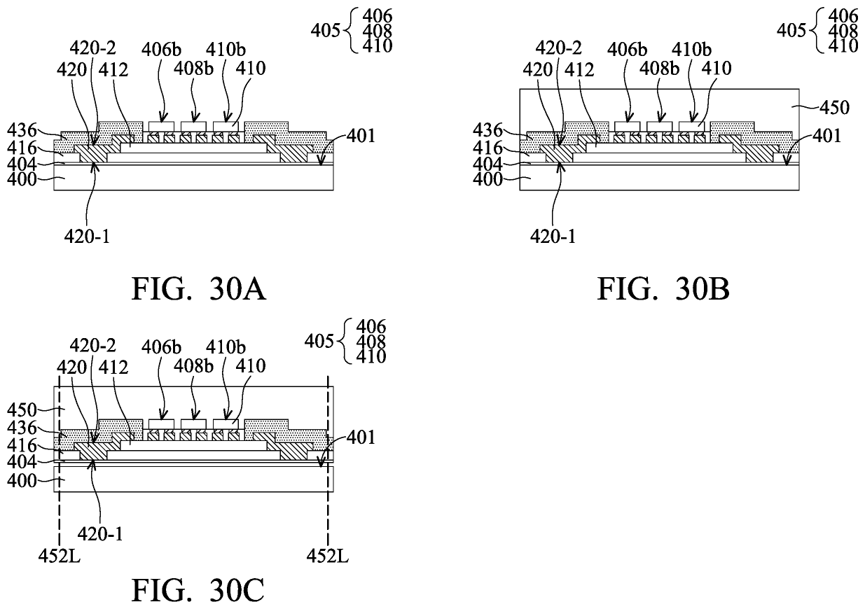

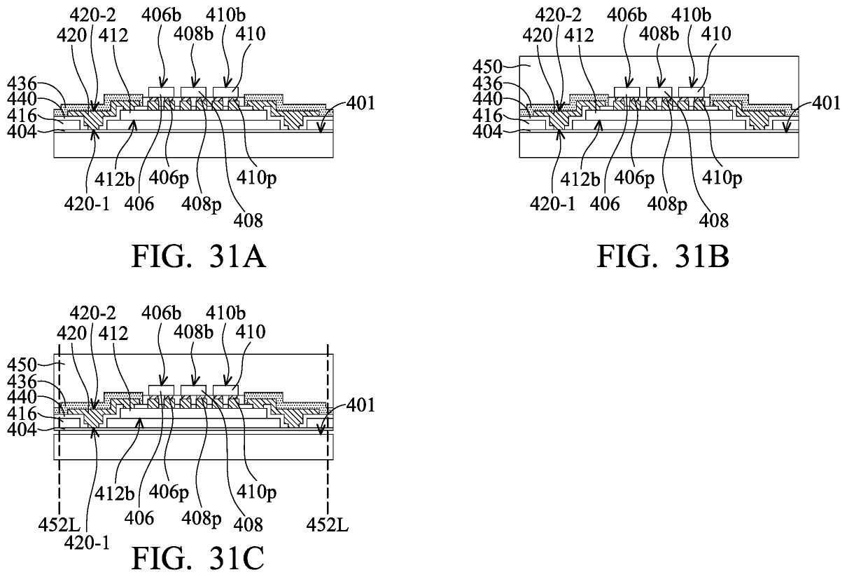

FIGS. 31A-31C are schematic cross-sectional views at different stages of forming the micro light-emitting diode package structure 500p shown in FIG. 14 in accordance with some embodiments of the disclosure, and the reference numbers the same or similar as those previously described with reference to FIGS. 1-16, 17A-17K, 18A-18E, 19A-19J, 20A-201, 21A-211, 22A-221, 23A-23H, 24A-24H, 25A-25D, 26A-26G, 27A-27D, 28A-28F, 29A-29E and 30A-30C denote the same or similar elements.

As shown in FIG. 31A, after the processes similar to those shown in FIGS. 28A, 28B, and 29A-29C are sequentially performed, processes similar to those shown in FIG. 30A are performed to form the light-shielding layer 436 conformally covering the distributed Bragg reflector layer 440, the redistribution layer 420 and the control device 412 and surrounding the micro light-emitting diodes 406, 408 and 410.

Next, as shown in FIGS. 31B and 31C, the processes similar to those shown in FIGS. 28E and 28F are sequentially performed to form the flexible material layer 450 covering the light shielding layer 436, the distributed Bragg reflector layer 440, the control device 412 and micro light-emitting diodes 406, 408 and 410. Next, the carrier 400 is removed from the adhesive layer 404. Next, the light shielding layer 436, the distributed Bragg reflector layer 440, the flexible material layer 450 and the redistribution layer 420 are cut along the scribe lines 452L. Finally, the micro light-emitting diode package structure 500p as shown in FIG. 14 is formed. Compared with the micro light-emitting diode package structure 5001, the distributed Bragg reflector layer 440 of the micro light-emitting diode package structure 500p close to the electrodes 406p, 408p, 410p of the micro light-emitting diodes 406, 408 and 410 is formed before the redistribution layer 420 is formed. In addition, the light shielding layer 436 is formed after the micro light-emitting diodes 405 are massively transferred onto the carrier 400.

The micro light-emitting diode package structure and the method for forming the same in accordance with some embodiments of the disclosure may integrate the control device and micro light-emitting diodes in the same package structure to form a pixel package that can be individually/independently controlled. The micro light-emitting diode package structure includes a redistribution layer, a control device, micro light-emitting diodes and a flexible material layer. The control device and the micro light-emitting diode are disposed on and electrically connected to the redistribution layer. The flexible material layer covers the control device and the micro light-emitting diodes, wherein the micro light-emitting diodes are in contact with the flexible material layer. In some embodiments, the micro light-emitting diode package structure further includes a distributed Bragg reflector layer close to the electrodes of the micro light-emitting diodes and in contact with the redistribution layer in order to increase the luminous efficiency of the micro light-emitting diode package structure. In some embodiments, the micro light-emitting diode package structure further includes a light shielding layer disposed between the redistribution layer and the flexible material layer, which can improve the contrast of the micro light-emitting diode package structure. In some embodiments, the control devices and the micro light-emitting diodes may be disposed on the same side or opposite sides of the redistribution layer. Alternatively, the micro light-emitting diodes can be disposed directly above the control devices, such as a thin film transistor device, to further reduce the size of the micro light-emitting diode package structure. The micro light-emitting diode package structure in accordance with some embodiments of the disclosure can further reduce the volume of the package structure for application in small-pitch displays, such as wearable display devices.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A micro light-emitting diode package structure, comprising:
a redistribution layer;
a control device disposed on and electrically connected to the redistribution layer;
a plurality of micro light-emitting diodes disposed on and electrically connected to the redistribution layer; and
a flexible material layer covering the control device and the micro light-emitting diodes, wherein the micro light-emitting diodes are in contact with the flexible material layer.

2. The micro light-emitting diode package structure as claimed in claim 1, wherein the control device comprises a micro driver integrated circuit device, a micro control integrated circuit device, a thin film transistor device or a combination thereof

3. The micro light-emitting diode package structure as claimed in claim 1, wherein the micro light-emitting diodes comprise electrodes, wherein the redistribution layer is in contact with the electrodes, and wherein the micro light-emitting diodes respectively have back surfaces located away from the electrodes, and the flexible material layer is in contact with the back surfaces of the micro light-emitting diodes.

4. The micro light-emitting diode package structure as claimed in claim 3, wherein a back surface of one of the micro light-emitting diodes is a rough surface.

5. The micro light-emitting diode package structure as claimed in claim 1, further comprising:
a light-shielding layer disposed between the redistribution layer and the flexible material layer, and surrounding the micro light-emitting diodes.

6. The micro light-emitting diode package structure as claimed in claim 3, further comprising:
a distributed Bragg reflector layer close to the electrodes of the micro light-emitting diodes and in contact with the redistribution layer.

7. The micro light-emitting diode package structure as claimed in claim 6, wherein an area of the distributed Bragg reflector layer is between 10% and 95% of a total area of a top surface of the micro light-emitting diode package structure in a plan view.

8. The micro light-emitting diode package structure as claimed in claim 1, wherein the redistribution layer has a first side wherein the control device and the micro light-emitting diodes are disposed on the first side.

9. The micro light-emitting diode package structure as claimed in claim 3, wherein the control device has a back surface and a contact pad, and the back surface is away from the contact pad, wherein the back surface of the control device is level with the back surfaces of the micro light-emitting diodes.

10. The micro light-emitting diode package structure as claimed in claim 1, further comprising:
a first insulating layer disposed between the redistribution layer and the flexible material layer, and surrounding the control device and the micro light-emitting diodes.

11. The micro light-emitting diode package structure as claimed in claim 10, wherein the control device has a back surface, wherein the back surface of the control device is exposed from the first insulating layer.

12. The micro light-emitting diode package structure as claimed in claim 10, wherein the redistribution layer has a second side, and wherein the micro light-emitting diode package structure further comprises:
a second insulating layer disposed on the second side; and
bonding pads passing through the second insulating layer and electrically connected to the redistribution layer.

13. The micro light-emitting diode package structure as claimed in claim 1, wherein the redistribution layer has a first side and a second side opposite the first side, and wherein the control device is disposed on the first side, and the micro light-emitting diodes are disposed on the second side.

14. The micro light-emitting diode package structure as claimed in claim 13, wherein the micro light-emitting diodes has sidewalls and electrodes, wherein the flexible material layer is in contact with the sidewalls and the electrodes of the micro light-emitting diodes.

15. The micro light-emitting diode package structure as claimed in claim 13, wherein the micro light-emitting diodes partially overlap the control device.

16. The micro light-emitting diode package structure as claimed in claim 13, further comprising:
a third insulating layer disposed on the first side of the redistribution layer and in contact with the control device.

17. The micro light-emitting diode package structure as claimed in claim 16, wherein the control device is located between the third insulating layer and the micro light-emitting diodes.

18. The micro light-emitting diode package structure as claimed in claim 16, further comprising:
a distributed Bragg reflector layer conformally covering the third insulating layer and in contact with the first side of the redistribution layer; and
bonding pads disposed between the third insulating layer and the distributed Bragg reflector layer, and electrically connected to the redistribution layer.

19. The micro light-emitting diode package structure as claimed in claim 16, further comprising:
a light shielding layer disposed on the second side of the redistribution layer and conformally covering the redistribution layer.

20. The micro light-emitting diode package structure as claimed in claim 19, wherein the flexible material layer is in contact with the light shielding layer.
